(19) United States
(12) Patent Application Publication
(10) Pub. No.: US 2018/0270435 A1
(43) Pub. Date: Sep. 20, 2018

(54) SYSTEMS AND METHODS FOR OPTICAL PERCEPTION

(71) Applicant: Symmetry Sensors, Inc., San Carlos, CA (US)

(72) Inventor: Vincent Y. Chow, San Carlos, CA (US)

(21) Appl. No.: 15/921,944

(22) Filed: Mar. 15, 2018

Related U.S. Application Data
(60) Provisional application No. 62/472,422, filed on Mar. 16, 2017.

(51) Int. Cl. H04N 5/378; H01L 27/146

(52) U.S. Cl. CPC H04N 5/378; H01L 27/14643; H01L 27/14625

(57) ABSTRACT

A system and method for optical perception can include a current confining pixel (CCP) that includes a detector pair, the detector pair including a first detector and a second detector, coupled together in an inverse polarity configuration such that the current confining pixel defines a sense node and a reference node together forming a differential output across the pair of detectors. The system and method can include a plurality of CCPs arranged in a CCP array, coupled together in any suitable manner; receiving, at a current confining pixel (CCP), an input signal; generating a differential output signal based on the input signal; and, analyzing an output of a CCP.

### CROSS-REFERENCE TO RELATED APPLICATIONS

This application claims the benefit of U.S. Provisional Application No. 62/472,422, filed 16 Mar. 2017, which is incorporated in its entirety by this reference.

### TECHNICAL FIELD

This invention relates generally to the optical perception field, and more specifically to new and useful systems and methods for optical signal detection and processing in the optical perception field.

### BACKGROUND

In the field of optical perception, conventional systems often rely on downstream processing of images and other signals (e.g., scattered light signals) to extract information. This has several disadvantages, such as amplification of noise present in the raw perceived signals (e.g., by applying a uniform gain to the signal in low-signal environments), high processing power requirements (e.g., for object detection and classification), addition of latency to perception and control architectures (e.g., latency due to the time required to process the raw signals), high bandwidth requirements (e.g., due to the need to preserve signal information until processing can be performed to sort high value information from low value information), and the like. Attempts to mitigate these and other various disadvantages using conventional approaches result in increased noise, power requirements, reduced sensitivity, and reduced dynamic range solutions. With conventional approaches, coprocessors and high-level software often face the bulk of complex signal processing that can greatly impact power consumption, cost, and size of the final product.

Thus, there is a need in the optical perception field to create new and useful systems and methods for low-noise, low-power, high-sensitivity, high-dynamic-range optical detection. This invention provides such new and useful systems and methods.

### BRIEF DESCRIPTION OF THE FIGURES

FIG. 1 depicts a schematic illustration of an example embodiment of a system for optical perception;

FIG. 2 depicts a flowchart of an example implementation of a method for optical perception;

FIG. 3 depicts an example schematic illustration of polarity encoding in relation to the system and method for optical perception;

FIG. 4 depicts an example configuration of a variation of the system for optical perception;

FIGS. 5A and 5B depict example configurations of detector pairs of a variation of the system for optical perception;

FIGS. 6A-6F depict example relative orientations of detector pairs of variations of the system for optical perception;

FIG. 7 depicts an example application of a variation of the system for optical perception including a vernier line;

FIG. 8 depicts an example configuration of a variation of the system for optical perception including a current confining pixel array;

FIG. 9 depicts an example current confining pixel array connectivity configuration of a variation of the system for optical perception;

FIGS. 10A-10B depict a time-series of a synthetic rotation in relation to the system and method for optical perception;

FIG. 11 depicts an example configuration of a variation of the system for optical perception;

FIG. 12 depicts an example of a portion of the system for optical perception;

FIG. 13 depicts an example configuration of signal processing circuitry of a processor of a variation of the system for optical perception;

FIG. 14 depicts an example configuration of the system for optical perception in a particle detection application using an LED light source;

FIG. 15 depicts an example configuration of the system for optical perception in a particle detection application using a laser light source;

FIG. 16 depicts an example packaging configuration of the system for optical perception usable in various applications;

FIGS. 17A-17B depict example split supply and single end configurations, respectively, of a portion of an example embodiment of the system for optical perception; and

FIG. 18 depicts a schematic of an example implementation of an actuator of an example embodiment of the system for optical perception.

### DESCRIPTION OF THE PREFERRED EMBODIMENTS

The following description of the preferred embodiments of the invention is not intended to limit the invention to these preferred embodiments, but rather to enable any person skilled in the art to make and use this invention.

### 1. Overview

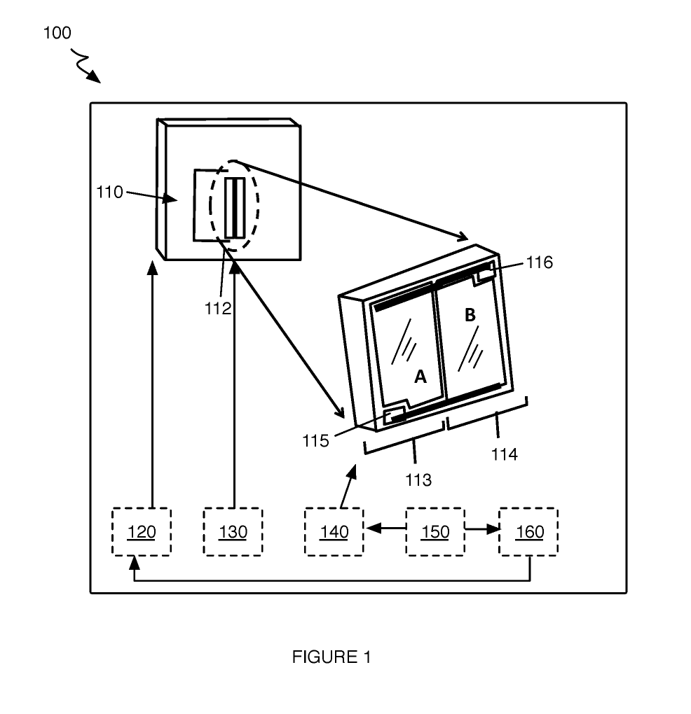

As shown in FIG. 1, an embodiment of the system 100 for optical perception includes: a current confining pixel (CCP) 110 that includes a detector pair 112, the detector pair 112 including a first detector 113 and a second detector 114, coupled together in an inverse polarity configuration such that the current confining pixel 110 defines a sense node 115 and a reference node 116 together forming a differential output across the pair of detectors 112. In additional or alternative embodiments, the detector system 100 can include a plurality of CCPs arranged in a CCP array 111, coupled together (e.g., at the respective sense and/or reference nodes) in any suitable manner, as described in further detail below. The system 100 can optionally include a light source 120, a biasing element 130, an actuator 140, a processor 150, a preconditioner 160, and any other suitable component.

The system 100 functions to transduce a single-ended, optical domain input signal into a differential, electronic domain output signal. The system 100 can also function to generate a comparison between an input signal and a reference signal in the optoelectronic domain, and output a trinary state (e.g., negative, zero, positive) based on the comparison. The system 100 can also function to sensitively detect input signal modulations (e.g., due to light scattering particles, active phase injection, physical modulation such as vibration, etc.). The system 100 can also function to encode polarity switching (e.g., bipolarity) into a unipolar input signal to generate a bipolar output signal (e.g., a symmetric AC output signal, an asymmetric AC output signal, etc.). The system 100 can also function to perform analog computation in the optoelectronic domain behind the sense node (e.g., within the CCP, upstream of the sense node, etc.). The system 100 can also function to generate pure white noise (e.g., as a basis for random number generation). The system 100 can also function to transform single-ended detectable inputs (e.g., scalar valued input signals) into differential outputs in a high-sensitivity, low-noise, high-dynamic-range manner. The system 100 can also function to transform a non-optical input signal into an optical input signal. The system 100 can also function to sense non-optical signals at a CCP configured to generate a signal voltage (e.g., across the sense node and reference node) and/or current (e.g., out of the sense node) in response to non-optical signals (e.g., electromagnetic radiation outside of the optical domain, acoustic signals, In variations, the system 100 can additionally or alternatively function to: detect inputs having a predetermined form (e.g., a one-dimensional pattern of optical intensities, a two-dimensional pattern of thermal intensities, etc.) and output a signal that indicates that the input signal matches or does not match the predetermined form; output a trinary-state logic signal having one of three possible discrete states (e.g., positive, negative, and zero; high, medium, and low; etc.); output a reduced-order signal wherein analog computation is performed upstream of (e.g., within the circuit prior to) the sense node and the reference node; output a directed vector map of the position of a perceived object as a function of time; and/or perform any other suitable detection function. However, the system 100 can additionally or alternatively have any other suitable function.

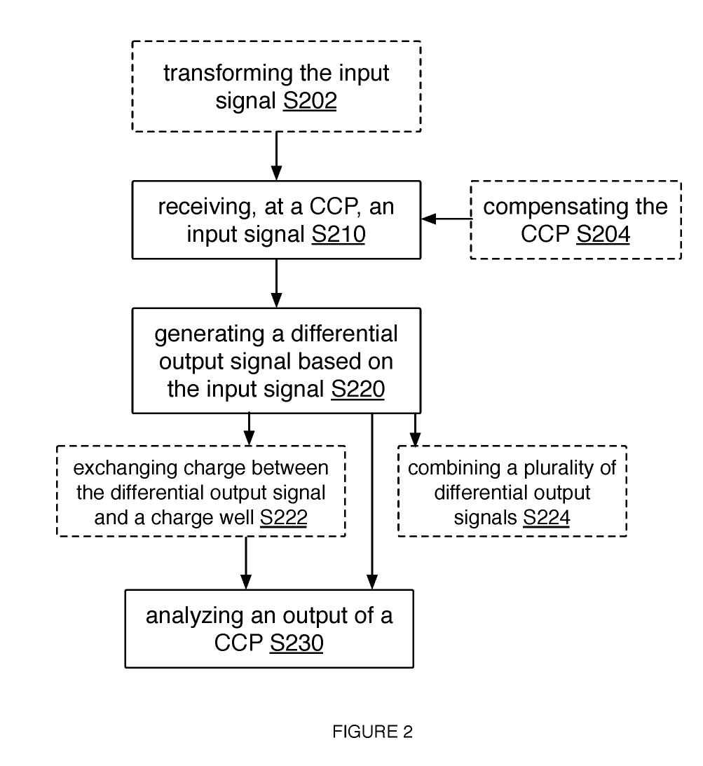

As shown in FIG. 2, an embodiment of the method 200 for optical perception includes: receiving, at a current confining pixel (CCP), an input signal S210; generating a differential output signal based on the input signal S220; and, analyzing an output of a CCP S230. The method 200 can optionally include: transforming the input signal prior to receiving the input signal at the CCP S202; compensating the CCP S204; exchanging charge between the differential output signal and a charge well S222; and, combining a plurality of differential output signals generated at a plurality of CCPs into a single differential output signal S224.

The method 200 functions to utilize one or more CCPs for optical perception. The method 200 can also function to utilize one or more CCPs for non-optical perception. The method 200 can also function to perform computation (e.g., analog computation, digital computation) in the optical domain and/or optoelectronic domain. The method 200 can also function to produce logical outputs in response to optical input signals. The method 200 can also function to perform any one or more of the functions described above in relation to one or more variations of the system 100, and/or any other suitable system for optical perception or non-optical perception, using a system substantially similar to one or more variations of the system 100. However, the method 200 can additionally or alternatively have any other suitable function.

The system 100 and method 200 can be used in conjunction with, implemented at, and/or executed by various related systems, mechanisms, and/or devices which may be improved by perception abilities, such as one or more user devices, output mechanisms (e.g., outputs), input mechanisms (e.g., inputs), communication systems, additional sensors, a power supply, a location system, and any other suitable system, subsystem, and/or component.

Examples of a user device used in conjunction with variations of the system 100 (e.g., wherein a CCP or CCP array is embedded within a user device, removably coupled to a user device, an integrated component of the user device, etc.), method 200, and/or variations thereof include: a tablet, smartphone, mobile phone, laptop, watch (e.g., mechanical watch, network connected watch, etc.), wearable device (e.g., network connected glasses, network connected headgear), and/or any other suitable user device. The user device can include power storage (e.g., a battery), processing systems (e.g., CPU, GPU, memory, etc.), user outputs (e.g., display, speaker, vibration mechanism, etc.), user inputs (e.g., a keyboard, touchscreen, microphone, etc.), a location system (e.g., a GPS system), sensors (e.g., non-CCP sensors and other optical sensors, such as light sensors and cameras producing single-ended signals; orientation and/or position sensors, such as accelerometers, gyroscopes, and altimeters; audio sensors, such as microphones, etc.), data communication system (e.g., a WiFi module, BLE, cellular module, etc.), or any other suitable component.

Outputs can include: displays (e.g., LED display, OLED display, LCD, etc.), audio speakers, lights (e.g., LEDs), tactile outputs (e.g., a tixel system, vibratory motors, etc.), or any other suitable output.

Inputs can include: touchscreens (e.g., capacitive, resistive, etc.), a mouse, a keyboard, a motion sensor, a microphone, a biometric input, a camera, a joystick, a videogame controller, or any other suitable input or input mechanism.

Communication systems used in conjunction with the system 100, method 200, and/or variations thereof can include one or more radios, transmitters, transceivers, IR transceivers, telecommunication relays, optical fibers, electrical signal carrying wires, or any other suitable component. The communication system can be a long-range communication system, a short-range communication system, or any other suitable communication system. The communication system can facilitate wired and/or wireless communication. Examples of the communication system include: 802.11x, Wi-Fi, Wi-Max, WLAN, NFC, RFID, Bluetooth, Bluetooth Low Energy, BLE long range, ZigBee, cellular telecommunications (e.g., 2G, 3G, 4G, LTE, etc.), radio (RF), microwave, IR, audio, optical, wired connection (e.g., USB), or any other suitable communication module or combination thereof.

Additional sensors (e.g., non-CCP-related sensors, sensors that transform a non-optical signal into an optical signal, etc.) used in conjunction with the system 100, method 200, and/or variations thereof can include: cameras (e.g., visual range, multispectral, hyperspectral, IR, stereoscopic, etc.), orientation sensors (e.g., accelerometers, gyroscopes, altimeters), acoustic sensors (e.g., microphones), optical sensors (e.g., photodiodes, etc.), resonant sensors (e.g., MEMs oscillators, piezo-oscillators, etc.), temperature sensors, pressure sensors, flow sensors, vibration sensors, proximity sensors, chemical sensors, electromagnetic sensors, force sensors, or any other suitable type of sensor.

A power supply used in conjunction with the system 100, method 200, and/or variations thereof can include a wired connection to electrical mains power and/or an AC-to-DC converter having any suitable output voltage, a wireless connection (e.g., inductive charger, RFID charging, etc.) to such a power source, a battery or other electrostatic energy storage device (e.g., secondary or rechargeable battery, primary battery, a non-rechargeable battery, a supercapacitor, a capacitor, etc.), energy harvesting system (e.g., solar cells, piezoelectric harvesting systems, pyroelectrics, thermoelectrics, etc.), or any other suitable system. In some variations, the system 100 and/or variations thereof can be unpowered, passive components (e.g., operative in a photovoltaic mode, a passive mode, an uncompensated mode, etc.).

A location system used in conjunction with the system 100, method 200, and/or variations thereof can include a GPS unit, a GNSS unit, a triangulation unit that triangulates the device location (e.g., user device location) between mobile phone towers and public masts (e.g., assistive GPS), a Wi-Fi connection location unit, a WHOIS unit (e.g., performed on IP address or MAC address), a GSM/CDMA cell identifier, a self-reporting location information, or any other suitable location module. Variations of the method 200 can include mapping optical perception outputs (e.g., of one or more CCPs at a location, coupled to a user device, etc.) in relation to a geographic area or other physical space using one or more location systems as described above.

### 2. Benefits

Variants of the systems and methods can confer several advantages and/or benefits.

First, variants of the technology can provide a balanced optical detection configuration (e.g., an optical balance beam) with inherent compensation of detected background signals. In such variants, a CCP can generate a differential signal output proportional to a difference between background signals detected at the detection surface(s) of the CCP and signals present above background that are incident more (or less) on one (or the other) of the two detectors of the pair of detectors of the CCP. Due to the reversed polarity configuration of the CCP, photocurrent or photo voltage generated in one or the other detector by an input signal incident on both detectors is balanced by the opposing detector and confined within the loop formed by the detector pair, such that no voltage difference or signal current is detectable between the sense node and the reference node of the CCP. The ability and high-sensitivity of the detector pair in transforming a normally single-end signal into a differential signal enables many perception characteristics to be determined upstream of the sense node (e.g., within the CCP loop via analog computation) for simplified detection, classification, and other perceptive operations. For example, in a particle detection application, coincident events wherein particles are simultaneously passing over the detector pair and scattering light from the light source, the frequency content of such signals reveal particle attributes (e.g., two smooth surface solid light-blocking particles, versus one solid light-blocking and one refractive, will reveal different coincident signal signatures representative of the relative composition of the particle pairs). In other examples, probe light intensity can be increased to improve the signal-to-noise ratio of the output signal without the drawbacks of increased intensity in conventional systems (e.g., saturation, glow illumination, etc.). Variants of the technology may not be hindered by strong incident illumination, thus SNR performance gains can take advantage of the brightest probe light intensity permissible. For every doubling of the light intensity, SNR can increase by a factor of root 2.

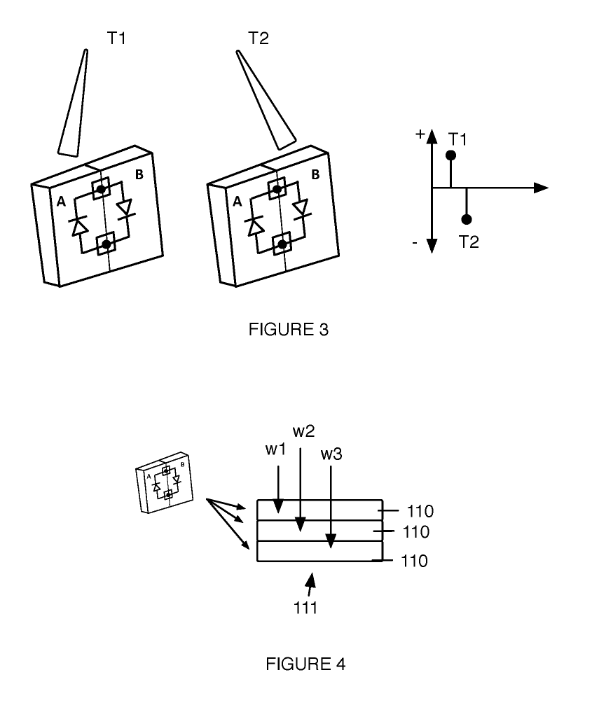

Second, variants of the technology can enable polarity signal encoding of unipolar signals (e.g., transient signals, static signals, etc.). For example, a spatially varying optical signal (e.g., inherently positive in intensity value) detected at a CCP will have a first portion encoded with positive polarity (e.g., incident upon a first detector) and a second portion encoded with a negative polarity (e.g., incident upon a second detector coupled to the first detector in an inverse polarity configuration). In another example, a temporally varying signal (e.g., a scattered light signature from a moving particle that is inherently positive in intensity) will be encoded at the differential output of the CCP as a bipolar signal, corresponding to the first polarity of the first detector and the second polarity of the second detector (e.g., as shown in FIG. 3). In related examples, combined disruption (e.g., from shadowing, diffraction and scattering) in the background forms a signature signal pattern that will instantaneously flip in polarity as the centroid point of the signature pattern crosses the boundary region between the detectors of the CCP. This enforced-symmetry converts all such input signals into symmetric AC signals where the pulse width, rise-fall times and peak-to-peak variations are discernible (e.g., and can reveal multiple particle attributes for size, density and flow dynamics in such applications). It also enables the use of simple phase-lock techniques to sense and integrate very weak signals (e.g., associated with submicron particles, refractive index fluctuations in transparent media, etc.).

Third, variants of the technology can enable can enable analog computation behind the sense node of the CCP in the optical and/or optoelectronic domain. This can minimize noise injection due to performance of analog and/or digital computation in the electronic domain (e.g., related to dark currents, amplification, op-amp noise characteristics, etc.). In examples, such variants can enable analog computation of an optical center of mass of a scene, in the context of optical perception. For example, a CCP can be configured to rotate at a rotation frequency while a scene is imaged onto the detection surface. At each time point during rotation, the differential output signal encodes (e.g., as a trinary state) which detector of the pair of detectors the optical center of mass of the image resides within; thus, over a series of time points collected over a full 360° rotation of the CCP, the point at which the optical center mass is centered on the separatrix (e.g., vernier-line) between the first and second detector of the CCP will generate a balanced (e.g., zero) output and thereby indicate the azimuthal position of the optical center of mass. In related examples, a linear CCP array can be rotated in a similar manner to determine both a radial and azimuthal position of the optical center of mass. In such variants, division of signal processing functions between hardware (e.g., in the analog optoelectronic domain) and software (e.g., in the digital domain) is enabled with the flexibility offered by this and other variants of the technology. This is because, for example, the sense node of the CCP can perform the majority of the signal detection work as an analog computer element by filtering and pulling out desired signals away from background and noise.

Fourth, variants of the technology can enable passive generation of a trigger based on injected polarity inversion of a detected signal (e.g., a forced zero-crossing of a signal). For example, a laser light source can be used to illuminate a CCP in a spatially asymmetric manner such that a positive differential output signal is generated; in response to deflection of the laser beam perpendicular to the separatrix (e.g., dividing line between the two detectors of the CCP), the differential output signal will cross through a zero value, enabling triggering (e.g., of an alarm system, of a notification system, etc.) based on the zero crossing without the need for threshold detection, signal processing downstream of the sense node, similar multi-bit reads (e.g., wherein a zero value represents a single bit read), or other further processing techniques.

Fifth, variants of the technology can enable generation of white noise output (e.g., true-random noise, pure white noise), which can be used as a truly random number generator (e.g., in lieu of a pseudo-random number generator) in a small form factor (e.g., on-chip). Due to the balanced configuration, in examples wherein a light source is used to uniformly illuminate the CCP detection surfaces, noise at the sense node is shot-noise limited. Since shot noise is frequency independent, it is true white noise, and the noise signal can be sampled from the sense node and reference node as a differential output signal and used in various applications (e.g., random number generation based on the normalized value of the noise signal).

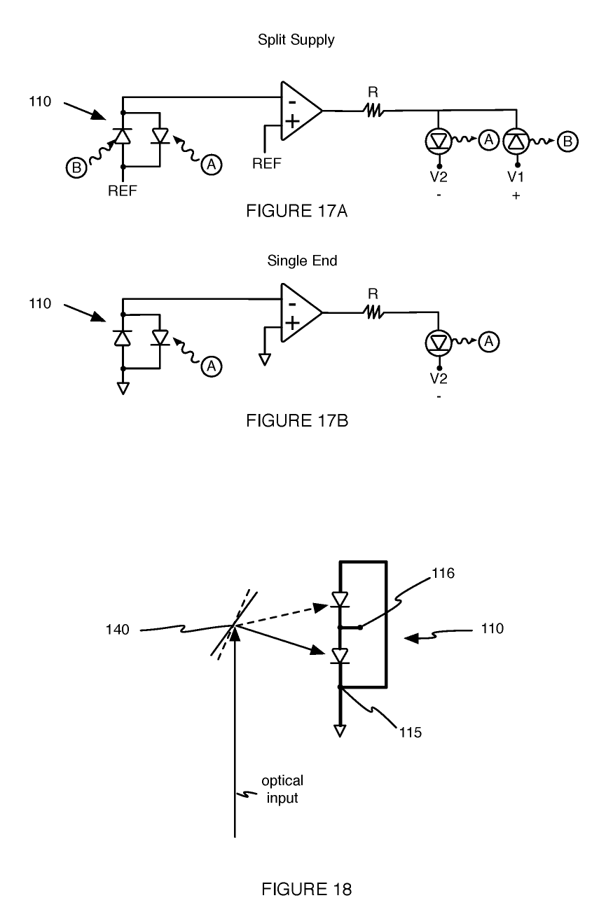

Sixth, variants of the technology can enable adaptive rejection of common mode signal. The common mode signal can be a background signal (e.g., a background image, a background intensity, a background intensity distribution, etc.), an applied bias (e.g., uniform illumination of a detection surface or rear surface of one or more detectors of the CCP), and/or any other signal common to the mutually electrically coupled detectors of a CCP or CCP array. Rejection of the common mode signal is enabled by the “locking” of the signal in the loop formed by the CCP, such that the signal is not perceptible at the differential outputs (e.g., the sense node and reference node). Adaptive rejection is enabled by actively compensating the CCP (e.g., by backside illumination of one or the other detector of a detector pair, insertion of a voltage source in the CCP loop, etc.) such that the zero-level of the differential output is adjustable. For example, an uncompensated background image on a CCP array may result in an array of voltage outputs from the CCPs of the CCP array (e.g., the initial common mode signal), and adaptive rejection of the common mode signal can be performed by illuminating one detector of each CCP using a keyframe (e.g., a projected copy of the uncompensated background image, an applied set of voltage biases mimicking the signal of the background image, etc.) such that the array of voltage outputs is substantially equal to zero (e.g., a zero-rich dataset, a compensated output, etc.). In further examples, as shown in FIGS. 17A-17B, adaptive common mode rejection (e.g., noise mitigation) can be enabled using an optically-based negative feedback amplifier wherein a photodiode (e.g., an isolated photodiode) is used for the feedback element (e.g., instead of a resistor, instead of an RC or RLC network, etc.). This example configuration can provide clean amplification (e.g., substantially noise free amplification) of the differential output signal (e.g., obtained from the sense node) by eliminating sources of high Johnson noise and the parasitic capacitance and/or inductance of a feedback resistor that would otherwise be further amplified at the output of the negative feedback amplifier. In this example configuration, the output of an operational amplifier drives a feedback resistor (Rf) in series with a photodiode that is biased into the turn-on region by a voltage supply (e.g., wherein the photodiode emits light in proportion to the drive signal from the operational amplifier). The light from the photodiode is coupled into one side of a CCP detector (e.g., one detector of the CCP is illuminated by the photodiode output signal). The sense node of the CCP is connected to the feedback negative input node of the operational amplifier. The CCP feedback current will maintain the sense node at the same potential as the positive reference voltage to maintain stability. Amplifier gain can be determined by the value (e.g., resistance) of Rf. This example optically-coupled feedback configuration enables low sense node capacitance, high sense node impedance, high bandwidth and high first stage gain for increased SNR performance compared to conventional technologies. The noise performance in this example and related configurations is shot noise limited, but the output noise is substantially white noise (e.g., its pure random property is preserved and/or enhanced, provides low and/or nonexistent undesired DC bias, etc.), which can enable enhanced phase-locked integration detection of weak signals (e.g., which the operational amplifier is used to amplify) otherwise obscured within random noise.

Seventh, variants of the technology can enable output of floating and/or offset differential signals having a high SNR. Such variants can include isolating a CCP (e.g., electrically isolating) from its surroundings (e.g., a ground plane, an earth ground, etc.) such that both the sense node and the reference node float above a ground potential or reference potential by an arbitrary amount, while continuing to enable differential signal output. Because the output of the CCP is differential (e.g., between the sense node and reference node) and optical in provenance (e.g., versus purely electronic), the CCP in such variants is less susceptible to electrical noise that can otherwise impact signals in conventional systems.

Eighth, variants of the technology can enable sensitive detection of low-amplitude resonances in input signals. In examples wherein the resonant input signals are detected asymmetrically between detectors of a CCP, conversion of the resonant modulation in the signal to a differential output results in a substantially noise-free (e.g., shot-noise limited) amplification of the modulation in the optoelectric domain. Asymmetric detection can be actively generated (e.g., via modulating the input signal using an acousto-optic modulator or other suitable modulator, modulating the detector position using a piezoelectric stage or other suitable mechanical modulator, etc.) or passively generated (e.g., already present in the input signal).

Ninth, variants of the technology can enable multi-wavelength and/or multi-frequency band detection simultaneously using a plurality of CCPs. In an example, the plurality of CCPs can be configured in a stacked array of collinear CCPs. CCPs can be fabricated using differing semiconductors, doped semiconductors, thicknesses, and other fabrication parameters that determine the peak photoabsorption wavelength and penetration depth of light as a function of wavelength. Accordingly, a structure such as that shown in FIG. 4 can be fabricated that generates a set of differential outputs from a stacked CCP array wherein each CCP has a peak sensitivity in a differing wavelength range (e.g., light frequency band). In other examples, high-angle and low-angle incident light sources can be of tunable multi-color LED or VCSELs that operate in at least two wavelengths; such capability can enable increased characterization sensitivity which can, for example, distinguish detectable signatures based on wavelength-dependent responses (e.g., particles caused by combustion can be distinguished from non-fire particles or scatterers such as dust and water vapor).

Tenth, variants of the technology can enable pattern matching between an input signal and a known, selected, and/or predetermined key signal. The pattern matching can be a linear pattern match; for example, the system 100 can include a linear array of serially-linked CCPs individually compensated against a key sequence, such that when the linear array detects an overall signal sequence that matches the key sequence, the aggregate sense node and reference node of the serially-linked CCPs outputs a match output (e.g., a zero, a positive signal, and/or any other suitable output indicative that the key sequence is matched). The pattern matching can additionally or alternatively be a two-dimensional pattern match; for example, the system 100 can include a two dimensional array of CCPs interconnected into clusters (e.g., wherein each cluster includes a plurality of serially linked CCPs, a plurality of CCPs linked in parallel, etc.), such that each cluster is compensated (e.g., by a bias element) based on a keyframe (e.g., a two-dimensional mapping of signal intensity values corresponding to a background image, a key sequence in two dimensions, etc.). In this example, the output of the two-dimensional pattern match is a match output (e.g., a zero) from each cluster when the keyframe (or equivalent, portion thereof, etc.) is detected at the cluster of CCPs, and a non-match output (e.g., +1, −1) when any signal other than the keyframe is detected. The pattern matching can be passive (e.g., wherein the CCP is compensated by structural asymmetries such as relative detector element sizes between the first and second detector, wherein the CCP is uncompensated, etc.) or active (e.g., wherein the CCP is actively compensated by an electrical bias, an optical bias, etc.). Pattern matching can be performed as a single-bit read, wherein the output of the network of CCPs is a single bit defining whether a match was obtained (e.g., a zero) or not (e.g., any value other than zero).

Eleventh, variants of the technology can enable operation of one or more CCPs in a photovoltaic (PV) mode, photocurrent (PC) mode, and/or a combination of the PV and PC modes (e.g., a first subset of a CCP array can be operable in PV mode and a second subset of the CCP array can be operable in PC mode, a CCP can be operable in either the PC or PV mode, etc.).

Twelfth, variants of the technology can enable continuously monitoring a CCP sense node at a coupled charge well (e.g., referenced to the reference node of the CCP or a different CCP in a CCP array or cluster) without saturating. The symmetric nature of the noise allows charge to be continuously pulled from the sense node and/or pulled from the charge well (depending on the instantaneous polarity of the noise value) such that the charge well does not fill unless a signal other than background is output by the CCP. Applications include low power and/or passive remote monitoring of a scene (e.g., in a remote area) wherein an image read from the CCP array only occurs upon filling of one or more charge wells of a coupled CCD array (e.g., when a change in the background is detected). Applications also include “staring” mode detectors, which continuously monitor a static or quasi-static scene and can detect transient phenomena having relatively short lifetimes (e.g., as compared to other scene dynamics) amidst bright background signal (e.g., without high shutter speeds). However, such variants can include any other suitable applications.

In addition, because of the small size of the CCP, the technology can be integrated into other devices, such as to enable low-power perception and object detection and characterization in mobile phones, kitchen appliances, vehicles, and other devices.

However, variants of the system and/or method can otherwise confer any suitable advantages and/or benefits.

### 3. System

As shown in FIG. 1, the system 100 for optical perception preferably includes: a current confining pixel (CCP) 110 that includes a pair of detectors 112, including a first detector 113 and a second detector 114, that defines a sense node 115 and a reference node 116. In additional or alternative embodiments, the system 100 can include a plurality of CCPs in a CCP array 111. The system 100 can optionally include a light source 120, a biasing element 130, an actuator 140, a processor 150, a preconditioner 160, and any other suitable component.

### 3.1 Current Confining Pixel

The current confining pixel 110 preferably includes a pair of detectors 112 including a first detector 113 and a second detector 114 connected in an inverse polarity configuration, as shown in FIGS. 1 and 3. The current confining pixel (CCP) 110 functions to contain current (e.g., actual current, virtual current, displacement current, charge flow, etc.) resulting from simultaneous (e.g., substantially simultaneous, contemporaneous, simultaneous within the time constant associated with the parasitic capacitance and/or inductance of the components, etc.) detection of an identical (e.g., substantially identical, equal in magnitude, equal in phase, equal within a detectability threshold range, equal within a quantum fluctuation threshold range, equal within a shot-noise limited range, etc.) signal at both of the pair of detectors 112 without surfacing the current (e.g., as a detectable voltage difference, as a detectable signal current, etc.) at the differential output (e.g., across the sense node and the reference node of the CCP). In instances wherein the signal received at the pair of detectors 112 is not identical as described, the difference between the signal (or portion of the signal) received at the first detector 113 and the second detector 114 is surfaced (e.g., as a detectable voltage difference, as a detectable signal current, etc.) at the differential output to a degree proportional to the difference (e.g., having a magnitude proportional to the difference in input signal magnitude between the first and second detector). Accordingly, the CCP 110 is preferably resistant (e.g., substantially impervious, substantially mitigating, etc.) to saturation (e.g., is insaturable) by an input signal (e.g., of any magnitude less than the survivability threshold of the physical constituent materials making up the CCP) in instances wherein the magnitude of the portion(s) of the signal detected at each of the first detector 113 and the second detector 114 are substantially identical, due to balancing of the optical inputs across the inverted detector pair. However, in variations, the CCP 110 can additionally or alternatively be configured to be saturable (e.g., at a threshold confined current magnitude).

The CCP 110 and components thereof are preferably fabricated via a semiconductor process in a monolithic configuration, but can additionally or alternatively be fabricated such that individual components are packaged separately and connected after fabrication (e.g., in individual surface mount component packages). The base material of the CCP is preferably silicon (e.g., in applications suitable for detecting optical signals in the visible range), including doped and undoped silicon in any suitable combination, but can additionally or alternatively include any suitable semiconductor material such as: carbon (e.g., crystalline diamond), germanium (Ge), gray tin, silicon compounds (e.g., SiC in 3C, 4H, 6H, and any other suitable forms), group VI semiconductors (e.g., sulfur/S₈, Se, Te, etc.), group III-V semiconductors (e.g., cubic BN, hexagonal BN, BN nanotubes, BP, Bas, B₁₂As₂, AlN, AlP, AlAs, AlSb, GaN, GaP, GaAs, GaSb, InN, InP, InAs, InSb, Type I, II, III super-lattice miniband structures, Type II strained layer super-lattice, etc.), group II-VI semiconductors (e.g., CdSe, CdS, CdTe, HgCdTe, ZnO, ZnSe, ZnS, ZnTe, etc.), group I-VII semiconductors (e.g., CuCl), group I-VI semiconductors (e.g., Cu₂S), group IV-VI semiconductors (e.g., PbSe, PbS, PbTe, SnS, SnS₂, SnTe, PbSnTe, Tl₂SnTe₅, Tl₂GeTe₅, etc.), group V-VI semiconductors (e.g., layered Bi₂Te₃), group II-V semiconductors (e.g., Cd₃P₂, Cd₃As₂, Cd₃Sb₂, Zn₃P₂, Zn₃AS₂, Zn₃Sb₂, etc.), oxide semiconductors (e.g., Tio₂ in anatase, rutile, and/or brookite phases, Cu₂O, CuO, UO₂, UO₃, Bi₂O₃, SnO₂, BaTiO₃, SrTiO₃, LiNbO₃, La₂CuO₄, etc.), layered semiconductors (e.g., PbI₂, MoS₂, GaSe, SnS, Bi₂S₃, etc.), diluted magnetic semiconductors (e.g., GaMnAs, InMnAs, CdMnTe, PbMnTe, etc.) magnetic semiconductors (e.g., FeO, NiO, EuO, EuS, CrBr₃, etc.), and any other suitable semiconductor materials (e.g., CuInSe₂, AgGaS₂, ZnSiP₂, As₂S₃, As₄S₄, PtSi, BiI₃, HgI₂, TlBr, Ag₂S, FeS₂, Cu₂ZnSnS₄, Cu₂SnS₃, etc.) in any suitable phase. The CCP and/or components thereof can additionally or alternatively be made of materials including microbolometers (e.g., amorphous silicon, vanadium oxide, Ti, YBaCuO, GeSiO, poly SiGe, BiLaSrMnO, protein-based cytochrome C, bovine serum albumin, etc.), pyroelectric materials (e.g., gallium nitride, caesium nitrate such as CsNO₃, polyvinyl fluorides, derivatives of phenylpyridine, cobalt phthalocyanine, lithium tantalate such as LiTaO₃, etc), piezoelectric materials (e.g., natural crystals, natural biological materials, synthetic crystals, Lead zirconate titanate and similar piezoceramics, PVDF and similar polymers, PNTs and similar organic nanostructures, III-V and II-VI semiconductors, etc.), and any other suitable materials.

In a specific example, the CCP no can be fabricated on a silicon chip using a CMOS process. The chip on which the CCP 110 is fabricated can additionally or alternatively be patterned with signal processing circuitry downstream (e.g., in signal propagation coordinates) of the output nodes (e.g., sense node, reference node, etc.) of the CCP, passive components as patterned features (e.g., capacitive features; inductive features; resistive features; features having any suitable specified and/or parasitic combination of capacitance, inductance, and/or resistance, etc.), sampling nodes (e.g., locations wherein signals can be tapped), and any other suitable patterned elements. Fabrication preferably includes lithography (e.g., photolithography), but can additionally or alternatively include plasma etch, ion milling, chemical etch, and/or fabrication by any suitable semiconductor manufacturing methodology and/or technique.

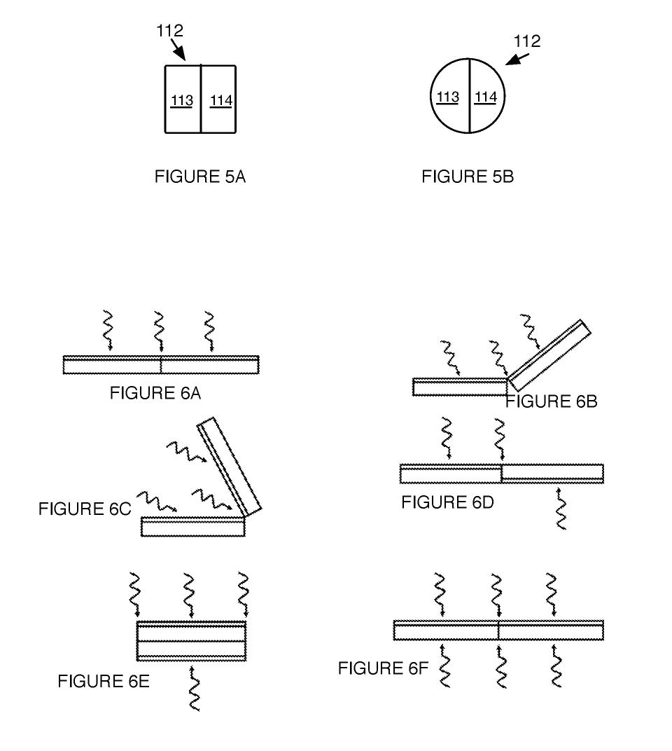

The detector pair 112 functions to confine the current within the CCP upon detection of a symmetric input signal (e.g., equal in magnitude between each detector) and to generate a differential output (e.g., across the sense and reference nodes) upon detection of an asymmetric input signal. The detector pair 112 can also function to provide the detection surface of the CCP 110 (e.g., the surface at which electromagnetic radiation input signals are transduced into electrical signals via generation of electron-hole pairs in the semiconductor material). The detector pair 112 can have any suitable size (e.g., the detection surface can have any suitable area, the area can be sized according to the application, such as based on the relative magnitude of particles to be detected, etc.), based on the patterning process and/or other fabrication method (e.g., a micron process, a 10 nm process, a macro process, etc.). The detector pair 112 can define any suitable shape (e.g., surface area shape). For example, the detector pair 112 can define a rectilinear outline in a manner similar to a unitary pixel, as shown in FIG. 5A. In another example, the detector pair 112 can define a circular outline, wherein the first and second detector each define half of a bisected circle, as shown in FIG. 5B. However, the detector pair can additionally or alternatively define any suitable shape and/or surface area.

In a specific example, the detector pair 112 includes two P-I-N photodetectors (e.g., the first detector 113 and second detector 114, a PIN photodiode, etc.), which can be represented by the letters “A” and “B,” respectively, as shown in FIGS. 1, 3, and 4. The photodetectors in this example can define near-functionally identical active areas such that they are abutted along one edge and electrically isolated by a thin boundary region. The width of the boundary region, in this and related examples, can be fabricated to be as small as possible (e.g., within the limit of the fabrication process); alternatively, however, the width of the boundary region can be selected and defined at a specified width greater than a minimum width afforded by the fabrication process (e.g., based on the detector application). In this example and related examples, the two P-I-N photodetectors may be electrically interconnected with electrically conductive material in a parallel inverse manner to achieve the inverse polarity connectivity configuration. In particular, in this example, the electrically conductive material connects the N side of photodetector A to the P side of photodetector B through contact holes in each photodetector, and also connects to a contact pad. Similarly in this example, conductive material connects the P side of photoconnector A to the N side of photoconnector B through contact holes and connects to contact pad. The aforementioned layout is an example configuration of the stable two-node (e.g., sense node and reference node) differential aspect of the CCP 110.

The pair of detectors 112 of the CCP 110 can be configured in various relative arrangements. For example, the first detector 113 and second detector 114 can be coplanar, wherein the active surface (e.g., detection surface, photosensitive surface, phonon-sensitive surface, etc.) of each detector is at the same side of the coplanar plane (e.g., as shown in FIG. 6A) or wherein the active surfaces of each detector are on opposing sides of the plane (e.g., as shown in FIG. 6D). In other examples, the surfaces of the first and second detectors can define an angle (e.g., occupy intersecting planes, as in FIGS. 6B and 6C), which can be a right angle, an acute angle (e.g., as shown in FIG. 6C), and/or an obtuse angle (e.g., as shown in FIG. 6B). In still further examples, the first detector 113 and second detector 114 can be arranged back-to-back, as shown in FIG. 6E, such that the active surface(s) are arranged in opposing directions. In any of the aforementioned examples or similar examples, the first and second detectors need not be directly adjacent, and can be separated by any suitable distance and maintain the relative angular arrangement described. In further example configurations, the first detector 113 and second detector 114 can be entirely separate and modular, and interconnected via the inverse polarity configuration, and maintain the current confining differential output capacity.

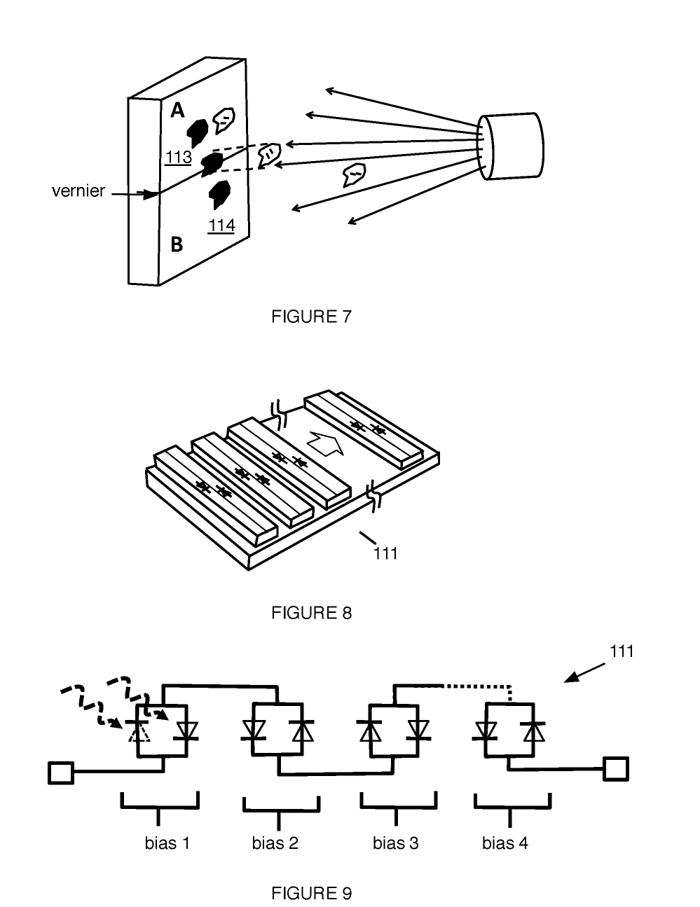

In some variations, the first detector 113 and second detector 114 of the detector pair 112 can be separated by a vernier-line, as shown in FIG. 7. In some examples, the vernier-line can define a fixed width (e.g., an inactive portion of the CIP surface between the first and second detectors), whereas in other examples, the vernier-line can define an infinitesimal width (e.g., the virtual crossover line between the first detector and a directly adjacent second detector of the detector pair). In examples wherein the vernier-line defines a fixed width, the width can be determined based on desired perception targets (e.g., a width can be selected that corresponds to an average particle size in a particle detector application of the CCP), and/or be determined using any other suitable basis.

Various configurations of the detector pair 112 (e.g., as shown in FIGS. 6A-6F) can afford different performance attributes (e.g., detection volume, signal bandwidth, sensitivity, etc.) to match unique requirements for various applications (e.g., particle detection). The active light sensing area (e.g., detection surface) of each detector faces toward the incident probe light beam shown by light rays for left, vernier-line center, and right of the detector pair 112. The substrate or backside of the detector pair 112 can be non-light-sensitive, less sensitive (e.g., devoid of any sensitivity enhancing coatings or materials), or equivalently sensitive as the front side. In an alternative configuration, the obtuse angle can provide a greater solid angle of view of the region within the V-confined apex, and can be matched to narrow frontal probe light beams (e.g., from a light source including a collimated light emitter such as a laser). In an alternative configuration, an acute angle can further increase the solid angle of view and SNR as the probe light beam is further narrowed and concentrated (e.g., by using any suitable laser). In further alternative configurations, combining frontal and rear light beam sources can facilitate compensation or bias of one or the other detector of the detector pair (e.g., to balance a keyframe, to balance a match sequence, etc.). For example, a configuration that is also planar but inverts one detector to sense an isolated light source while the front detector views the probe light (e.g., and/or scattering signals from particles) can be used. Such configurations can enable suppression of background illumination to maintain a constant zero-null signal state at the detector-pair sense node (e.g., across the sense node and reference node). In this example configuration, the probe scan light now may be steady, modulated or pulsed but the sense node zero-null state (in the absence of particle signals) can be maintained. Since the detector pair 112 can be described as a balance beam sensitive to light instead of mass weights, the light signal can sensed at the top or bottom of each detector (e.g., at the detection surface) to produce identical responses at the sense node 115. Similarly, each side of the balance beam can include multiple detector units connected together wherein each can sense a separate probe light signal, but the net differential output can be detected at one sense node. In an alternative configuration, the detector-pair 112 can be arranged in a sandwich layout, wherein the folded edges are at one side and the vertex is at the opposite side, while sensing both frontal and rear input signals. This example arrangement can permit high-density packing and tiling blocks of detector pairs 112 (e.g., of CCPs 110), with background light suppression, to form many geometric layouts to match application needs (e.g., in relation to CCP arrays 111 as described below).

In variations, one or more surfaces of the detector pair 112 can include morphological features (e.g., to enhance performance, to guide airflow, to enhance detection sensitivity, etc.). For example, in a particle detection application, the surface can define one or more shallow V-grooves etched into the surface to increase near-field contact probability of nanometer particles. The V-channels can act like a guide trench (e.g., flow guide) that can confine the particle direction of motion to follow the groove of the trench path and thereby increase detection probability (e.g., by increasing proximity to the detection surface and therefore increasing the sharpness of the scattering shadow signature, by increasing residence time of the particle in the vicinity of the surface, etc.). In a related example, one or more electrodes can be coupled to the V-groove surfaces and, during operation, excited by voltage waveforms (e.g., AC waveforms, DC waveforms, a superposition of AC and DC waveforms, etc.) to attract or repel particles. In another example, in a scene monitoring application, the surface can define a region oblique to the angle(s) of incoming light rays (e.g., spherical, parabolic, angular, etc.) that acts as a focusing element for concentration of light rays onto a portion of the detector surface and/or another surface (e.g., as a parabolic mirror, a flat mirror, etc.). However, the surfaces of each detector of the detector pair of each CCP can additionally or alternatively include any suitable morphological features.

Variants of the system 100 include arrangements of a plurality of CCPs 110 into a CCP array 111. As shown in FIG. 8, the CCP array 111 can be a linear array. In alternative variations, the CCP array 111 can be a two-dimensional array (e.g., a rectilinear array, a circular array, etc.), a three-dimensional array (e.g., patterned on the surface of any suitable 3D shape), and/or have any other suitable shape or arrangement. The CCP array 111 can be fabricated (e.g., etched, patterned, etc.) into a single monolithic chip, formed from a plurality of individually fabricated CCP units, and any suitable combination of the aforementioned (e.g., formed from a plurality of multi-CCP arrays fabricated in a single chip).

The CCP array 111 can have various connectivity schemas among nodes of CCPs in the array. For example, a rectilinear array of CCPs including columns and rows can be made up of serially-connected CCPs in each column, whereas the rows are unconnected (e.g., the 2D CCP array is made up of a series of linear CCP arrays as columns). In another example, a two dimensional array of CCPs including columns and rows can be made up of rows wherein each CCP in each row is connected in parallel between two rails (e.g., an upper rail connected to the sense node of each CCP in the row, and a lower rail connected to the reference node of each CCP in the row), whereas the columns are unconnected (e.g., the 2D CCP array is made up of a series of linear CCP arrays as rows). In further examples, a CCP array 111 can include serially connected subsets and parallel-connected subsets within the same CCP array 111. However, a CCP array 111 can be otherwise suitable connected. In a CCP array 111 having interconnected CCPs, each subset of CCPs which are interconnected preferably produce a combined output across a sense node of one of the subset of CCPs and a reference node of another of the subset of CCPs. The combined output is preferably made up of a superposition of the differential output signals that would be generated by each CCP in the absence of interconnectivity between the CCPs in the CCP array (e.g., a linear superposition); however, in some variations, the combined output can be a nonlinear superposition and/or any other suitable combination of differential output signals, defined by the node interconnectivity.

In a variation, an example of which is shown in FIG. 9, a CCP array includes a serially-connected linear array of CCPs, wherein each of the linear array of CCPs is biased away from a “o” reference state (e.g., illuminated such that the differential output signal is nonzero) by a predetermined bias amount corresponding to each CCP of the array. In this variation, in cases wherein the input signal detected by each of the serially-connected linear array of CCPs matches the predetermined bias amount (e.g., offsets the predetermined bias amount), the collective output (e.g., the differential output between the reference node/sense node of the first in the array and the sense node/reference node of the last in the array) is substantially equal to zero (e.g., a logical zero). In this variation, in cases wherein the input signal detected by the CCP array does not match, the collective output is nonzero (e.g., a logical 1, a logical −1, any output besides a logical zero, etc.). In a related variation, a matching input signal produces a nonzero collective output and a non-matching input signal produces a logical zero collective output.

In a specific example of this variation, a linear CCP array is coupled to an optical fiber and actively biased such that the matching sequence is a predetermined message portion encoded in a header packet being transmitted over the optical fiber. In response to a logical zero (e.g., a match) output by the linear CCP array, the message behind the header packet is automatically and instantaneously switched (e.g., routed) to a destination within the network associated with the matching message portion (e.g., a message destination). Because the linear CCP is actively biased (e.g., by back illumination of each CCP, by asymmetric illumination of each CCP, etc.), the matching sequence (e.g., key sequence) can be rapidly shifted to enable routing of messages having various predetermined destinations.

In some variations, the CCP array 111 can define clusters of CCPs within the CCP array. Clusters are preferably made up of interconnected CCPs that collectively produce one of a trinary set of outputs (e.g., logical −1/negative, logical 0, or logical 1/positive), but can additionally or alternatively be made up of interconnected CCPs that produce any suitable collective output (e.g., an analog differential output). The clusters can be configured in various ways within the array, such as in an ordered configuration (e.g., a checkered cluster pattern in a 2D array of CCPs), an ad hoc manner (e.g., a spackled pattern in a 2D array of CCPs), and any other suitable manner.

In some variations, a CCP array 111 can be arranged as a set of logic gates. One or more CCPs of the array can be interconnected to perform a logic computation (e.g., performed in the optoelectronic domain among the one or more CCPs) upon an input signal. The logic computation is preferably a trinary logic computation (e.g., having three possible output states), but can additionally or alternatively be a bivalent or Boolean logic computation, a multi-valued logic computation having a number of states greater than three (e.g., obtained by grouping compensated CCPs that adjust the output to a positive offset, otherwise suitably obtained, etc.)

In variations of a CCP array 111, each of the plurality of CCPs can include detector pairs 112 in various relative arrangements (e.g., wherein each CCP includes a detector pair having the same relative arrangement as each other CCP, wherein a first subset of CCPs of the plurality includes corresponding detector pairs having an acute relative angle and wherein a second subset of CCPs of the plurality includes corresponding detector pairs having a coplanar relative arrangement, etc.). For example, a CCP array 111 can be made up of CCPs wherein each of the detector pairs 112 is configured in a back-to-back manner (e.g., a first detector 113 defines a first detection surface presented in a first direction, and the second detector 114 defines a second detection surface presented in an opposing direction wherein the back side of the second detector 114 is adjacent to the back side of the first detector 113); this configuration enables projection of a keyframe on the back side (e.g., on the set of second detectors of the CCP array) and output of logical zero values from each CCP that matches the keyframe (e.g., that detects an input signal at the first detector equal to the signal from the keyframe detected at the second detector arranged at the back side). However, the pair of detectors 112 can additionally or alternatively be otherwise suitably arranged.

In another variation, as shown in FIG. 4, the CCP array 111 can be collinearly stacked. A stacked collinear CCP array can function to perform the optical perception function(s) described above, at various depths within a vertical configuration (e.g., wherein the various depths correspond to associated penetration depths and/or wavelengths of light). Each CCP of the stacked CCP array can be made up of the same semiconductor material, or made up of different materials (e.g., having peak optical absorption sensitivity or quantum efficiency at different wavelengths, having different optical and/or radiative opacities, etc.). Each CCP of the stacked CCP array can define the same thickness, or define differing thicknesses (e.g., a top layer defining the top CCP can be thinner than a bottom layer in order to permit a larger quantity of photons to penetrate the top layer).

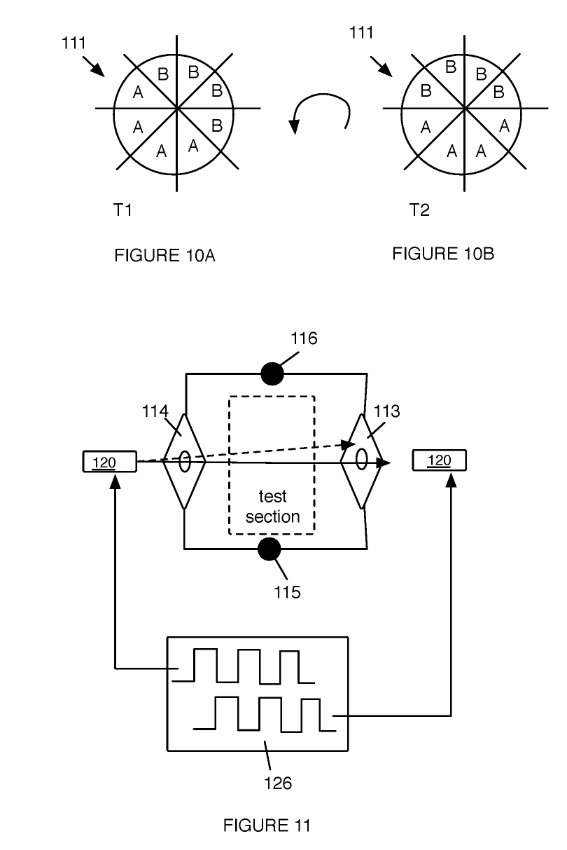

In some variations, the connectivity of CCPs in the CCP array 111 and/or detectors within each CCP of the CCP array 111 can vary as a function of time. The connectivity can physically vary as a function of time (e.g., via a switch fabric of bilateral switches that open or close electrical pathways between nodes of CCPs in the array), and/or vary as expressed in the collective output of the CCP array (e.g., via dynamic shifting of the nodes from which the differential collective output is read from the CCP array). In a variation of temporally variable connectivity, the CCP array can include a set of segmented electrodes that can be dynamically reconfigured into the first and second detectors of one or more CCPs. In a specific example of such variations, as shown in FIGS. 10A-10B, the CCP array ill is made up of a set of detector surfaces forming a segmented circular region. At a first time, as shown in FIG. 10A, a first subset of the set of detector surfaces (denoted by “A” in FIG. 10A) collectively form the first detector 113 and a second subset of the detector surfaces (denoted by “B” in FIG. 10A) collectively form the second detector 113. At a second time, as shown in FIG. 10B, the first and second subsets forming the first detector 113 and the second detector 114 can be shifted by drawing the collective output (e.g., differential output signal) from different nodes of the interconnected nodes. This process can be referred to as synthetic rotation (e.g., the detector surface corresponding to the first detector and second detector of a CCP seem to rotate with respect to the detected input signals, without physically rotating). In such examples and variations, the segmented electrode CCP array can be configured in various form factors, such as the circular form factor previously described, a checkerboard form factor, and any other suitable form factor. In a specific application, such a configuration enables determination of an optical center of mass of a scene by imaging a scene onto the set of detector surfaces in the segmented region and performing the synthetic rotation previously described. The optical center of mass (e.g., wherein optical intensity is considered as equivalent to physical mass) of the scene in such a case is located at the angular position of the synthetic rotation wherein the collective output is at a minimum (e.g., within the spatial resolution of the set of segments). The minimum of the collective output (e.g., the differential output across the two nodes from which, at a particular time point, the output is collected) can be directly measured (e.g., wherein the optical center of mass is located at the division between the two detectors) or indirectly measured (e.g., interpolated, wherein the optical center of mass is located between the division of a first detector pair at a first time and a second detector pair at a second time). In a related example configuration, the segmented detector can be further divided into concentric radial segments; in such examples, the optical center of mass can be determined (e.g., directly measured, interpolated, etc.) in both the radial and azimuthal coordinates. In the aforementioned variations and examples, the CCPs (e.g., the subsets of segments making up the CCP unit at any particular time during the synthetic rotation) can be uncompensated, actively compensated (e.g., by way of back illumination, inline bias elements, etc.), passively compensated (e.g., by asymmetric detector surface areas between segments), dynamically compensated (e.g., compensated in any suitable spatial configuration wherein the degree and/or intensity of compensation varies in time), and/or otherwise suitably compensated.

### 3.2 Light Source

The system 100 can include a light source 120. The light source 120 functions to generate light and to illuminate at least a portion of the detection surface of a detector (e.g., detector 113, detector 114) of the CCP 110. The light source 120 can include a light emitter 122, an optic 124, a modulator 126, and any other suitable component related to light generation and transmission. In some variations, the light source 120 can be an external light source reflected off of a scene to form an image; for example, in an area illuminated by the Sun or interior lighting, the light source can be the scattering objects (e.g., objects in the scene, which in such cases can act as the light emitter 122).

The light source 120 can include a lamp, a light emitting diode (LED), a laser, a heated filament, a fluorescent substance, and any other suitable source of light. The light source 120 can include a single light emitter or a plurality of light emitters. In variations including a plurality of light emitters, the light emitters can have a one-to-one correspondence with CCPs (e.g., of a CCP array), a one-to-one correspondence with detectors of a single CCP (e.g., a first light emitter associated with a first detector 113, and a second light emitter associated with a second detector 114 of a CCP 110), a many-to-one correspondence (e.g., a plurality of light emitters that illuminate a single CCP or detector), a one-to-many correspondence (e.g., a single light emitter that illuminates a plurality of CCPs or detectors), and any other suitable correspondence.

The light source 120 can be used to facilitate input signal collection (e.g., by provision of a background light that can be modulated by the presence of particles, objects, movement of objects, movement of scattering elements, etc.), as well as to provide compensation (e.g., acting as all or part of the biasing element 130 as described below).

The optic 124 functions to image the light source 120 (e.g., the light emitter 122 of the light source) onto the CCP 110. The optic 124 can include a lens, a set of lenses, a telescope, a spatial filter, an aperture, a prism, a phase plate, and any other suitable optical element configured to passively transform light from the light source (e.g., focus, diffuse, expand, contract, etc.). In a specific example, the optic 124 includes a simple lens defining a focal length, wherein the optic is arranged to produce an image of a scene that fills a circular CCP (e.g., separated from the CCP surface by a distance selected to fill the detection surface of the CCP with the image, based on the focal length of the lens). However, the optic 124 can include any other suitable optical elements otherwise suitably arranged.

The modulator 126 functions to modulate the light from the light emitter 122. Modulating the light from the light emitter can include injecting phase content of various types, such as: cycling the light emitter between “on” and “off”, modulating the intensity at a specific frequency, modulating the angle of incidence at a specific frequency, and/or otherwise injecting phase content into the input signal by way of modulating the light from the light emitter 122. The modulator 126 can include an acousto-optic modulator (AOM), an electro optic modulator (EOM), a piezoelectric modulator (e.g., to vibrate the light emitter), a wave generator (e.g., to duty-cycle the light source via a square wave driver or other suitable waveform), and any other suitable type of modulator.

In a specific example of the system 100, as shown in FIG. 11, including a modulator, a first and second light source, and a physically-separated first and second detector of the CCP, the modulator cycles two opposing light sources in mutually-exclusive duty cycles such that one or the other of the light sources is continuously on (e.g., emitting light), and only one of the two light sources is on at any given time. The detector surfaces of the opposing detectors each define an orifice through which the light emitted by the light source passes without illuminating the detector in the absence of a scattering element in the test section, as shown in FIG. 11. In some applications of this example configuration, descending particles can be detected in accordance with the low-noise, high-sensitivity methods described herein in relation to usage of the CCP while reducing stray light (e.g., common mode light) incident on each of the two detector surfaces.

In some variations, the system 100 can include one or multiple light sources aimed at high and shallow incident angles at the detection surface of the CCP. Each light source can further be single-element or dual-element types (e.g., depending on desired zero-null precision). The configuration of this variation can provide enhanced signature detection capabilities by creating long or stretched shadows on the detector surface. The resulting differential output signal from the CCP on which elongated shadows are present can be compared ratiometrically to differential output signals produced by incident light at a higher angle of incidence. One advantage of this multiple light ratio can include the generation of a detectable signature that improves both detection threshold and signature type characterization (e.g., particle detection limit thresholds and particle type characterization). For example, a signature resulting from a perceived object of a human shape may result in a ratiometric signature substantially different from a non-human shape (e.g., a pet), a human shape corresponding to a different human (e.g., a different member of a same household), and/or any other suitable perceived object shape.

### 3.3 Biasing Element

The system 100 can include a biasing element 130. The biasing element 130 functions to bias one or more of the detectors 113, 114 of the CCP (e.g., relative to one another, relative to a baseline to produce a symmetric offset, etc.). The biasing element 130 can include an electrical bias (e.g., a voltage source, a current source) placed in series within the CCP loop, an optical bias (e.g., a portion of the light source, a distinct light source, etc.), a physical bias (e.g., wherein the CCP is constructed with an asymmetric area ratio between the first and second detector, wherein the CCP is constructed with dissipative or resistive elements in parallel with the first or second detector, etc.), and any other suitable bias.

The biasing element 130 can be constructed as a part of the fabrication process and thereby be static in bias provision (e.g., as in the case of a physical bias), or can be dynamically applicable (e.g., as in the case of an optical bias, any other active bias, etc.). Application of bias by the biasing element 130 can be referred to as compensation elsewhere in this document; however, in variations, the system 100 and uses thereof in accordance with the method 200 or other techniques can include both compensating and biasing simultaneously or in lieu of one another.

In a specific example, the biasing element 130 includes an optical emitter arranged to illuminate a back side (e.g., a non-detection surface) of the CCP in an adjustable and asymmetric manner, such that the differential output of the CCP can be set to zero in the absence of an input signal. In a related example, the biasing element 130 includes an optical emitter arranged to illuminate the first detector only, without illuminating the second detector, at a front side (e.g., detection surface) of the first detector. In various applications of these and other related examples, the intensity of the output of the optical emitter can be adjusted to set the differential output of the CCP to any suitable value (e.g., zero, a predetermined threshold value, etc.).

In variations, the biasing element 130 can include a feedback control loop to maintain the differential output value at a set point. This feedback control loop is preferably a proportional-differential-integral (PID) controller, but an additionally or alternatively implement any suitable control paradigm to maintain the differential output value at a set point.

### 3.4 Actuator

The system 100 can include an actuator 140. The actuator 140 functions to actuate portions of the system 100. The actuator 140 can also function to inject phase content into the input signal by way of the structure of the CCP (e.g., instead of via modulating of the light source); this can, in variations, be used to modulate an input signal resulting from a passive source (e.g., a scattering object reflecting sunlight or interior room lights). Actuation can include vibration (e.g., dithering), rotation, slewing, and any other suitable motion.

In variations of the CCP 110 including a vernier-line or similar separation offset, usage of the CCP can include inducing a dithering motion of the detector along one axis (e.g., using a piezoelectric drive, stationary electro-drive birefringent optics, etc.) using the actuator 140 (e.g., to increase signal-to-noise performance of the CCP). This motion is preferably perpendicular to the vernier-line direction and injects polarity coding (e.g., bipolar coding, polarity modulation) into the detected signal, wherein the modulated signal has phase content proportional to the phase content of the motion. With this embedded +1 and −1 coding signal interweaved into the particle signal, synchronous lock-in signal extraction techniques can be used to sense low-intensity and/or noisy signals via phase-sensitive detection.

In another variation, the actuator 140 is attached to an optic of the light source and functions to rotate the image on the CCP to inject phase content into the input signal (e.g., angular position as a function of time). In this variation, the optic can be a mirror and the actuator can be used to rotate the mirror; alternatively, the optic can be any suitable optic actuatable by the actuator 140.

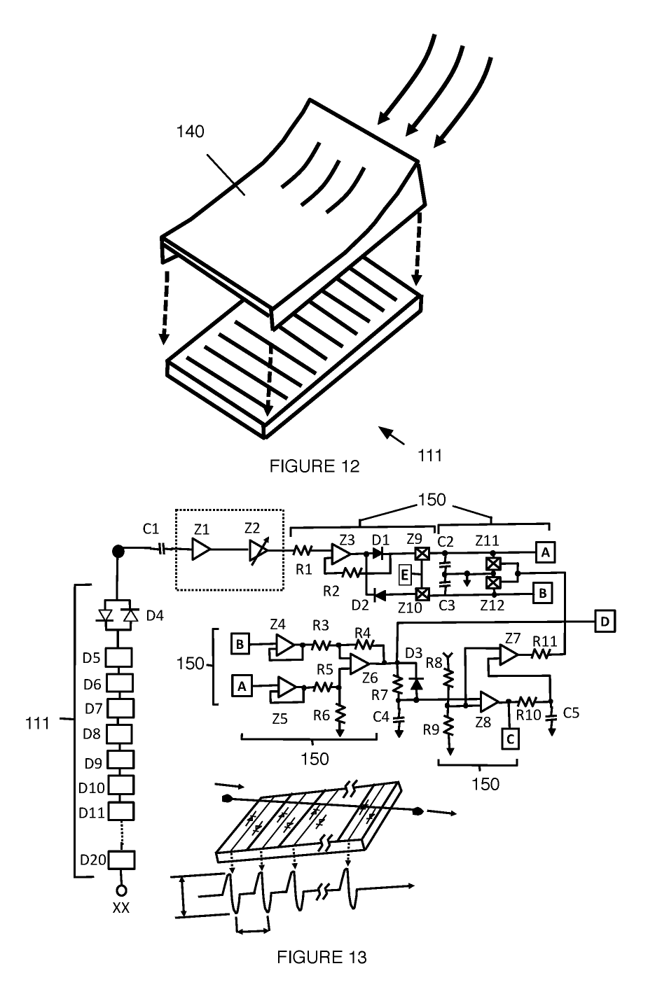

In another variation, the actuator 140 includes a passive flow actuator that functions to manipulate flow of fluids in the vicinity of the detection surface of the CCP. For example, as shown in FIG. 12, the actuator 140 can include a transparent light pipe louver structure can be arranged above a CCP array in order to induce a funnel effect on gas plume flow (e.g., wherein the configuration pushes particles towards the array detector surface).

In another variation, an example of which is shown in FIG. 18, the actuator 140 can include a dither mirror that alternately directs an optical input signal between a first detector and a second detector of the CCP. The dithering action of the mirror preferably generates a bipolar differential output signal that contains phase content substantially equivalent to the phase content injected via the dithering action of the dither mirror.

In further variations, the actuator 140 can include an enclosure or sub module, such as an acoustic module, that is coupled, either directly or indirectly, such as via a ported connection, to utilize a speaker diaphragm, electromagnetic drive, piezo element, or reciprocating element for a pumping action, to push air through or past the CCP at known flow rates.

### 3.5 Processor

The system can include a processor 150. The processor 150 functions to process the outputs (e.g., collective output, differential outputs, etc.) produced by one or more CCPs and/or CCP arrays as described above. The processor 150 can also function to implement, in whole or in part, the method 200 described in Section 4 below. Processing the outputs can include performing various analog domain and/or digital domain computations, such as: summing, subtracting, dividing, multiplying, Boolean operations, ternary or trinary logic operations, multi-value logical operations, and any other suitable operations.

The processor 150 can include various signal processing circuitry, an example of which is shown in FIG. 13. The form factor of the electronics can, in variations, permit an SMD package size for the system 100 that can be inclusive of circuitry. In this example, a CCP array with multiple elements (D4, D5, D6, D7, D8, D9, D10, D11, and up to D20) can be equated to a cascaded string of voltage sources (e.g., signal voltage sources). In the null state, all sources (D4 to D20) are at zero volts and therefore, the summed voltage at the sense node 115 referenced to the reference node 116 at (D20) is also zero volts. As a perturbation to the input illumination tracks across the CCP array, a series of bipolar zero-cross waveforms of characteristic peak-to-peak amplitudes are generated at each detector boundary vernier-line with substantially equal periods producing a tone burst (e.g., periodic signal persisting for a finite period of time). This tone burst can, in variations, be DC or AC coupled into the signaling circuitry. DC coupling is preferably used when background AC+DC levels are desired. AC coupling is preferably used when pulse tones signals are desired. However, AC and/or DC coupling can be used in any combination in alternative variations for any suitable purpose.

The pulse signals thus generated can be AC coupled through C1, and subsequently enter a preamplifier block with buffer and amplifier op-amps Z1 and Z2, respectively, as shown in FIG. 13. The amplified AC signal is the series of pulses from (D4 to D20) making up the tone burst. This signal can then be input into a bipolar peak-to-peak hold detector including input R1, feedback R2, blocking diodes D1 and D2, hold capacitors C2 and C3, and Sample Hold Switches Z9 and Z10. The peak-to-peak tone burst value can then be captured by C2 and C3 and fed to outputs of the network, until it is reset via switches Z11 and Z12. This signal can then enter into a circuit block at inputs (A) and (B) to an instrument amplifier circuit including buffers Z4, Z5 and instrument amplifier components R3, R4, R5, R6 and amplifier Z6. The instrument amplifier can transform the peak-to-peak signal into a ground referenced DC signal at the output of Z6.

The DC signal gate Z6 can enter an RC circuit consisting of R7, C4 and fast discharge diode D3. The voltage on C4 can increase from ground up to the maximum peak level at output of Z6. This RC signal can then enter a circuit block wherein a threshold comparator Z8 compares this signal with a trip point value (e.g., trigger value, threshold value), which can be determined by the voltage bridge of R8 and R9. Once Z8 triggers, the output C can send an interrupt signal to a microprocessor of the processor to read the DC peak value stored at output of Z6 connected to output D. Read time (e.g., a hold period for the value to be read) can be offered by delay components R10 and C5, but additionally or alternatively a reset signal can be applied at the output of Z7 that can discharge the peak-to-peak signal storage capacitors C2 and C3. In this example implementation, this signal processing cycle can repeat for every input signal signature sensed that exceeds the minimum level determined by the reference bridge R8 and R9.

Using the aforementioned example signaling circuit and/or any other suitable signaling circuit, a supporting microprocessor of the processor 150 can be alerted of perceived events wherein the detected signature exceeds the threshold value. Similarly, analog and digital circuitry can be patterned into a chip (e.g., the same chip in which the CCP is fabricated in examples) to form a fixed circuitry implementation (state machine) to relieve processing clock cycle burden on the support microprocessor. This can, in examples, function to prolong battery life in a portable or other low-power use case or application of the system 100.

### 3.6 Preconditioner

The preconditioner 160 functions to prepare signals for input into a CCP 110 as an input signal. The preconditioner 160 can also function to transduce non-optical signals into optical signals for input into a CCP 110 as an input signal. The preconditioner 160 can also function to inject phase content into the input signal. The preconditioner 160 can additionally or alternatively function to modify the input signal prior to detection at the CCP in any suitable manner.

While the input signal is preferably an optical input signal, in some variations the benefits and/or advantages of the CCP can be applied to non-optical signals upon transduction into an optical signal. For example, the preconditioner 160 can include an acousto-optic transducer that converts sounds waves into an emitted optical signal (e.g., a microphone that powers an LED). In another example, the preconditioner 160 can include a thermal-optical transducer that converts long- and/or short-wave IR signals (e.g., indicative of thermal activity) into optical signals (e.g., by way of electro-optic conversion, sandwiching of different semiconductor materials having different wavelength sensitivities, etc.). In another example, the preconditioner 160 can include a hapto-optic transducer that converts a touch signal into an optical signal (e.g., by way of an actuator that harvests mechanical energy and outputs a proportional optical signal). Various transducers that output an electrical signal proportional to any physical quantity can be configured to couple to an optical emitter, in accordance with the preconditioner 160 as described, such as: pressure transducers, thermocouples, thermistors, piezosensors, MEMs resonators, and any other suitable electrical transducer.

In some variants, the preconditioner 160 can inject phase content into the input signal prior to detection at the CCP 110. For example, the preconditioner 160 can include a waveform generator and an AOM driven by the waveform generator that deflects the input signal (e.g., wherein the input signal is a laser beam) in a periodic manner to inject phase content (e.g., modulate the signal). In another example, the preconditioner 160 can include one or more polarization filters that are arranged between the light source and the CCP and only permit passage of optical signals of a polarization associated with the polarization filter (e.g., 90° polarization, rotating polarization, etc.). However, the preconditioner 160 can otherwise suitably inject phase content and/or be otherwise suitably arranged.

### 3.7 System Examples

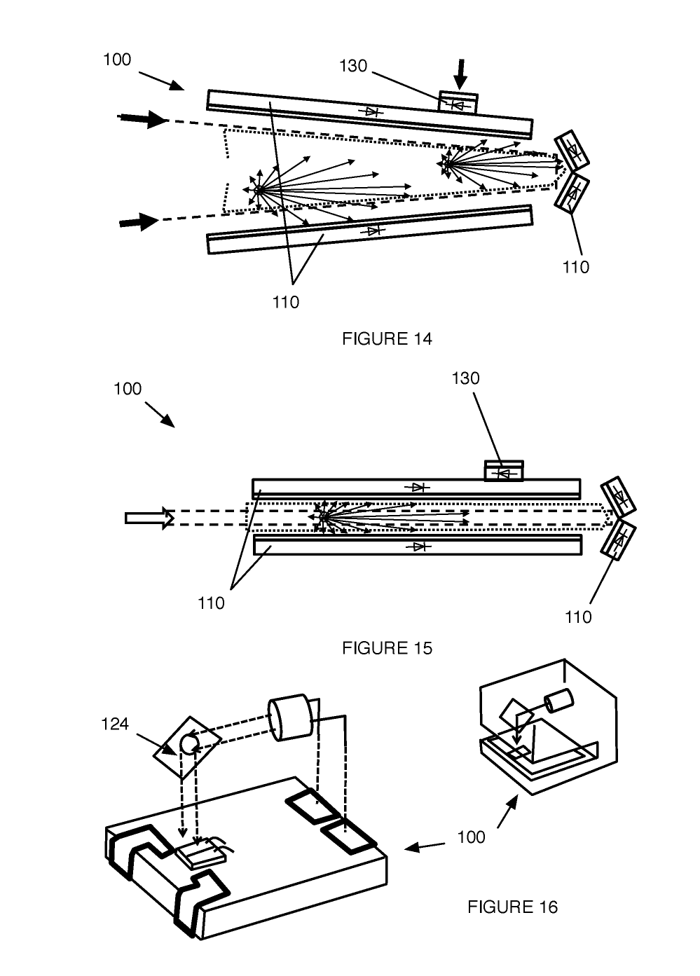

In a specific example as shown in FIG. 14, the system 100 can be used to detect simultaneously far-field, boundary layer, and near-field particle interaction properties with a light source. FIG. 14 depicts a configuration that is preferably used in cases including a non-laser type (e.g., LED) light source, while FIG. 15 depicts a configuration that is preferably used in cases including laser probe light as the light source. For both example configurations, the system 100 includes two CCPs arranged in a top and bottom symmetrical layout wherein the active areas (e.g., detection surfaces) of each facing opposing directions. This arrangement forms one side of the optical balance beam while a third detector forms the other side with an active area that is not viewing the sensing zone, but is arranged to sense a bias illumination from a controlled source. The circuit diagram shows the electrical circuit including the output sense node and reference node of this balance. A second detector-pair is arranged as an obtuse angle differential detector circuit that forms a second optical balance that is positioned with the active areas intercepting the probe light beam. In operation, probe light from an LED source or equivalent light source is focused into the sampling volume. Without particle presence, the background light (e.g., “glow”) from the probe light beam is fully cancelled by the bias illumination, as detectable at the differential output (e.g., at the sense nodes and reference node). The second balance is for direct-detection where the detectors of the CCP are aligned to sense the probe light beam at its centroid point. This preferably results in a differential output signal near zero-null (e.g., logical zero), at the second balance sense node, without particle presence. In related examples, a biasing element can be coupled to the second balance to permit automatic gain control and to maintain a mean-signal of zero at this sense node. With particle presence, flow is driven by diffusion or active airflow that enters the sampling volume from the open areas not occupied by the CCPs. Particles within the probe light zone can then result in light scattering that is detected by the parallel portions of the CCPs, while particles entering the direct detection zone have a high probability of dwelling within the V-channel of the base CCP. Thus, this example configuration enables extraction of boundary layer and near-field particle properties that adds to Mie scattering signals to yield particle-typing signatures with time-dependent flow patterns that can enhance particle-detection value in many applications.

The laser-based example configuration shown in FIG. 15 is similar to the configuration described, with the exception that a laser source is employed. Due to the narrow collimated beam, the detector arrangement can be parallel and close together in comparison to the LED-based configuration. The sampling volume in this example is now a parallel narrow channel permitting large solid-angles of view (e.g., compared to the V-shaped channel) to particles interacting with the laser light, which can improve the signal-to-noise ratio. For the CCP performing direct-detection, higher optical power enabled by the laser light source also increases SNR where the noise limit is from shot noise.

As shown in FIG. 16, a specific example of a package design of the system 100, using a surface mount 0603 device (SMD) package enabled by the miniaturizable nature of the CCP. For example, a detector chip including a CCP can be approximately 175 microns×175 microns in size and can be epoxy fixated to a ceramic substrate with dimensions of 1.6 mm by 0.8 mm patterned with four solder-reflow contact points around each corner. Wire bonds can interconnect the chip to the ceramic base. The optic of the light source can include a 90-degree reflector fixed above the detector pair (e.g., to steer probe light emitted by a LED, VSCEL or similar light source). In this example, a protective shell can be fitted over the completed ceramic subassembly. A window slot in the shell can enable particles to enter and be detected in accordance with the functionality and techniques described herein. However, related examples can include any suitable geometric variations to the dimensions described above.

In another example configuration, as shown in FIG. 13, a series of CCPS can be cascaded to form a linear or variable pitch CCP array. The CCP array can be affixed onto a SMD substrate, or otherwise suitably mounted. Such a configuration can enable tone burst detection. In a specific example of tone burst detection, the linear CCP array can include a number (e.g., twenty) of detector blocks (e.g., CCPs) spaced at a predetermined offset. The offset in this example functions to produce maximum tone response matched to a specific particle size, wherein the particle size is of the same order as the offset (e.g., in an analogous manner to an electronic bandpass filter). The linear CCP array can, during operation, output the sum of the number of signals (e.g., twenty signals) at the output nodes (e.g., sense node and reference node). The output nodes can, in examples, be wired and/or packaged as SMD outputs. In this example, the number of particle detection blocks can be designed as discrete units, but in related examples the number of CCPs in the array can be fully integrated as one array on a single silicon-chip along with support electronics. In operation as a particle detector, as a particle grazes along the surface of the cascaded detection array, a zero-cross bipolar pulse is output each time the particle traverses a CCP of the CCP array. The cycle period of pulses can be substantially constant due to the short span in travel, or the cycle period can be variable (e.g., due to flow dynamics). The series of sequential zero-cross pulse signals forms a tone burst signal with increased duration (e.g., due to the transit time of the particle over the array) that can enable sensing by phase-lock or bandpass filtering techniques. This configuration and operation can also enable time-division-integration (TDI) techniques (e.g., to be used to achieve maximum detection sensitivity for submicron particles). In further examples, multiple CCP arrays, each set with a different offset, can be cascaded to provide particle distribution and variation data as a function of time. Accordingly, a variable pitch CCP array can be included to add statistical process (SPC) control for special particle flow control applications.

### 4. Method

As shown in FIG. 2, an embodiment of the method 200 for optical perception includes: receiving, at a current confining pixel (CCP), an input signal S210; generating, at a CCP, a differential output signal between a sense node and a reference node based on the input signal S220; and, analyzing an output of a CCP S230. The method 200 can optionally include: transforming a precursor signal into the input signal S202; compensating the CCP S204; exchanging charge between the differential output signal and a charge well S222; and, combining a plurality of differential output signals generated at a plurality of CCPs into a single differential output signal S224.

In variations, the method 200 can include the implementation of any of the behaviors, techniques, and/or processes described above in relation to the system 100. The method 200 is preferably implemented using a CCP, CCP array, and/or variation thereof substantially as described above in Section 3; however, the method 200 can additionally or alternatively be implemented using any suitable components.

### 4.1 Preconditioning

The method 200 can optionally include Block S202, which includes: transforming the input signal prior to receiving the input signal at the CCP. Block S202 functions to place the input signal in condition for optical detection at the CCP, and thus Block S202 can include transforming a precursor signal of a non-optical nature into an input signal of an optical nature. Block S202 can also function to inject phase content into the input signal by, for example, modulating the CCP itself and/or the input signal. Block S202 is preferably performed by a preconditioner substantially as described above in Section 3, but can additionally or alternatively be performed by any suitable component. Block S202 is preferably performed prior to receiving the input signal at the CCP (e.g., in Block S210), but can additionally or alternatively be performed at any suitable time.

In a variation, Block S202 includes transforming a precursor signal into an input signal. In this variation, the precursor signal can be a non-optical signal such as a pressure signal, an electronic signal, an acoustic signal, a thermal signal, a flow speed signal, and any other suitable non-optical signal. The precursor signal can also be an optical signal that is not optimally detectable by the CCP in the absence of preconditioning; for example, the precursor signal can be an optical signal that is outside the ideal wavelength sensitivity range of the CCP, and Block S202 can include shifting the wavelength (e.g., using a nonlinear optical mixer, using a passive optical component, using a fluorescent medium that is pumped at the wavelength of the precursor signal and fluoresces at the target wavelength, etc.). However, the precursor signal can additionally or alternatively be any suitable signal.

In a variation, Block S202 includes injecting phase content into the input signal (e.g., prior to receiving the input signal at the CCP). Phase content can include any temporally varying quantity in relation to the signal; for example, Block S202 can include modulating the amplitude of the input signal as a function of time, modulating the spatial distribution of the signal as it is received at the CCP as a function of time, modulating the phase angle of the signal itself, and/or modifying any other suitable property of the signal as a function of time in order to inject phase content. Injecting phase content preferably includes monitoring the phase content as it is injected, so that the phase content can be extracted (e.g., demodulated) after generating the output signal at the CCP in accordance with one or more variations of Block S220 (e.g., as a part of analyzing the output in Block S230). Monitoring the phase content can include, for example, routing the modulation signal to an inversion block coupled to the output signal of the CCP for subsequent demodulation. However, Block S202 can additionally or alternatively include injecting phase content in any suitable manner.

In a first example, Block S202 includes modulating the CCP in order to inject phase content into the signal received at the CCP. Modulating the CCP can include vibrating the CCP (e.g., with a piezoelectric stage), rotating the CCP (e.g., using a rotation stage), and/or otherwise spatially or temporally modulating the CCP. Modulating the CCP can include adjusting the effective detection area of the CCP and/or components thereof; for example, in a CCP having segmented detector surfaces, spatially modulating the CCP can include adjusting the connectivity of the segments as a function of time and thereby adjusting the extent and/or orientation of the detector(s) of the CCP as a function of time. However, spatial modulation of the CCP can be otherwise suitably achieved.

In a second example, Block S202 includes modulating the input signal. Modulating the input signal can include cycling the input signal (e.g., according to a symmetric duty cycle, an asymmetric duty cycle, a variable duty cycle, etc.), acoustically modulating the input signal (e.g., using an AOM), electro-optically modulating the input signal (e.g., using an EOM), deflecting the input signal (e.g., via an AOM, EOM, etc.), phase-rotating the input signal (e.g., using a polarizer or polarization filter), and otherwise suitable modulating the input signal.

### 4.2 Compensating

The method 200 can optionally include Block S204, which includes: compensating a CCP. Block S204 functions to actively bias one or more detectors of the CCP. Block S204 can also function to set a zero-null point of the CCP. Block S204 can also function to zero out a differential output signal of a CCP.

Block S204 is preferably performed by a biasing element substantially as described above in Section 3, but can additionally or alternatively be performed by any suitable component. In variations, Block S204 can be performed by a light source (e.g., substantially as described above) wherein compensating the CCP includes optically compensating the CCP.

In a first variation, Block S204 includes providing a bias illumination. The bias illumination can be provided at a detection surface of a single detector (e.g., to provide an optical weight to one side of the CCP balance), at a backside of a single detector, at a detection surface or backside of both detectors of a CCP (e.g., to increase the overall input signal intensity without creating a differential output signal), and/or otherwise suitably provided. The bias illumination is preferably provided using a dedicated bias illumination light source (e.g., distinct from the probe light source that generates the input signal), but can additionally or alternatively be provided by a single light source (e.g., the probe light source that generates the input signal) and/or any suitable light source.

In a second variation, Block S204 includes providing a bias voltage. The bias voltage can be applied to a single detector of a detector pair (e.g., to adjust the zero null point, the CCP balance point, etc.), both detectors of a detector pair (e.g., to offset differential output signal by the bias voltage), and/or otherwise suitably applied. The bias voltage is preferably provided by an ungrounded voltage source (e.g., a battery, a plurality of batteries, a ballast capacitor, etc.) such that the CCP can remain floating; however, the bias voltage can additionally or alternatively be provided by any suitable grounded or ungrounded voltage source (e.g., an AC-DC converter, a mains-connected electrical power source, etc.).

In another variation, Block S204 includes compensating a CCP array. The CCP array can be uniformly compensated (e.g., wherein each CCP is compensated by the same amount) or non-uniformly compensated (e.g., wherein each CCP is compensated by a differing amount, wherein a subset of CCPs is compensated by a first amount and a second subset is compensated by a second amount, etc.). In one example, Block S204 can include non-uniformly compensating a CCP array according to a key sequence, wherein a matching input signal received at the CCP array (e.g., as in Block S210) results in a logical zero generated at the output node (e.g., as in Block S220), which can in turn be used to drive further behavior (e.g., as in Block S230). In another example, Block S204 can include non-uniformly compensating a 2D CCP array, wherein the sense nodes of each CCP are interconnected into a fully-connected network, according to a key frame, wherein a matching input signal received as an imaged scene on the 2D CCP array results in a logical zero generated at the output node. However, Block S204 can include otherwise suitably compensating a CCP array.

### 4.3 Receiving an Input Signal

Block S210 includes: receiving an input signal. The input signal is preferably received at a CCP, but can additionally or alternatively be received at a plurality of CCPs (e.g., a CCP array) or at any other suitable detector. Block S210 functions to convert the input signal into the optoelectronic domain within the CCP. Block S210 can also function to confine photocurrent generated by the detector pair of the CCP in the loop formed by the stable inverted-polarity node configuration. Block S210 is preferably performed using a CCP and/or CCP array substantially as described above in Section 3; however, Block S210 can additionally or alternatively be performed using any suitable component or detector.

In relation to Block S210, the input signal is preferably an optical signal. The optical signal can be a single-valued signal (e.g., the intensity of a single probe beam), a multi-valued signal (e.g., the two-dimensional distribution of intensity in an image), a multi-spectral signal (e.g., containing wavelength components from disparate portions of the electromagnetic spectrum, ranging from far IR to far UV, etc.), a time-varying signal, a spatially-varying signal, and any other suitable optical signal. In some variations, the input signal can be a non-optical signal; in such variations, the non-optical signal is preferably preconditioned into an optical signal (e.g., as in Block S202). However, in alternative variations, the CCP can be configured to convert non-optical signals directly into a current (e.g., a photocurrent) within the inverse-polarity looped configuration, and the input signal in such cases need not be an optical signal.

In relation to Block S210, the input signal can be received simultaneously at a plurality of CCPs. For example, in a CCP array in a stacked collinear configuration, the input signal can be received simultaneously by each CCP in the array (e.g., wherein first portions of the input signal having a greater penetration depth are received at a deeper layer in the collinear stacked array, and wherein second portions of the input signal having a shallower penetration depth are received at a shallower layer in the collinear stacked array contemporaneously with the first portions). In another example, the input signal can include a two-dimensional signal (e.g., an image), and portions of the image can be simultaneously received at each CCP in a 2D array (e.g., analogously to CCD pixels at the imaging plane of a camera system). However, the input signal can additionally or alternatively be otherwise suitably received at a plurality of CCPs.

In relation to Block S210, the input signal can be received sequentially. The input signal can be received sequentially at a single CCP; for example, a single CCP can encode an input signal into a time-varying ternary logic output (e.g., a −1, 0, or 1 generated in accordance with Block S220). The input signal can be received sequentially at a plurality of CCPs (e.g., a CCP array); for example, an imaged scene can be received over a series of time points at a 2D CCP array, and the individual CCPs of the array can be connected such that the ternary logic outputs of the CCPs trace the path of a moving object between frames in the image sequence. However, the input signal can additionally or alternatively be otherwise suitably received sequentially.

### 4.4 Generating an Output Signal

Block S220 includes: generating a differential output signal based on the input signal. Block S220 functions to convert the received single ended signal (e.g., in Block S210) into a differential output signal. Block S220 is preferably performed at a CCP substantially as described above in Section 3, but can additionally or alternatively be performed at any suitable balanced and/or differential detector. Accordingly, the differential output signal is preferably generated between a sense node and a reference node of a CCP as described. In variations, the differential output signal can be generated between a sense node of a first CCP and a reference node of a second CCP, wherein the first and second CCPs are connected in a CCP array (e.g., serially connected, connected in parallel, connected in a lattice network, etc.).

In relation to Block S220, the differential output signal is preferably proportional to a difference in magnitude between the portion of the input signal received at a first detector of the CCP and the portion of the input signal received at a second detector of the CCP (e.g., wherein the first and second detectors are connected in an inverse polarity configuration as described above in Section 3). While the differential output signal is preferably proportional to a difference in intensity magnitudes, the magnitude of the intensity of the signal at each detector can, in variations, be proportional to various other signal differences (e.g., wavelength, phase, polarization, angle of incidence, etc.); therefore, the differential output signal can be proportional to a difference in these other aforementioned properties and any other suitable properties that can be converted into a perceived intensity variation.

In a variation, Block S220 can include encoding polarity into the input signal to generate an alternating differential output signal. As an input signal is received in accordance with Block S210, the intensity of the input signal will be detected at either the first detector of the CCP or the second detector of the CCP. In variations wherein the input signal is modulated such that the majority of the input signal intensity alternates between the first and second detector, the generated output signal will be inherently bipolar due to the inverse polarity loop configuration of the CCP. Thus, temporal dynamics within the input signal can be resolved into an alternating polarity differential output signal, thereby encoding polarity into the signal. A differential output signal that has been thusly encoded with polarity can be used to increase the signal-to-noise ratio of the differential output signal, as discussed in more detail in relation to Block S230. Polarity encoding can be performed at over a large bandwidth and at a high frequency (e.g., limited only by the modulation frequency of the input signal modulator) because polarity encoding is performed in the optoelectronic domain (e.g., within the CCP) and is thus driven primarily by electron-hole generation and recombination dynamics.

In relation to Block S220, generating the differential output signal can be performed at a CCP operating in the photovoltaic (PV) or photoconductive (PC) modes. In the photovoltaic mode, each of the detectors of the CCP is preferably unbiased, and generates a current in response to photons received in the bandgap of the detector. In the photoconductive mode, each of the detectors of the CCP is preferably reverse biased, and generates a current in response to received photons within the increased (e.g., by the reverse bias) depletion junction. Though the PC mode can result in increased dark current, said dark current is preferably confined in the CCP loop as in other configurations, thereby minimizing observed dark-current noise across the sense node and reference node of the CCP. In either the PV or PC modes, Block S220 preferably includes confining the fraction of the current that corresponds to symmetric illumination of the inversely-connected detectors within the CCP loop. In some variations, Block S220 can include generating the differential outputs at CCPs that operate in either the PC or PV mode, simultaneously (e.g., wherein one detector is reverse biased into the PC mode and the other detector is in the PV mode, wherein a first CCP of a CCP array is operated in the PC mode and a second CCP of the CCP array is operated in the PV mode, etc.) and/or sequentially (e.g., in the PC mode for a first time interval, followed by the PV mode for a second time interval).

Block S220 can include Block S222, which includes: exchanging charge between the differential output signal and a charge well. Block S222 can function to enable a “staring mode” detector, wherein the detector (e.g., including the CCP and coupled charge well) is directly monitoring a differential value instead of a single-ended value (e.g., intensity as in a typical CCD or camera system). In variations, Block S222 can include alternately supplying charge to (e.g., by way of a positive differential output signal) and drawing charge from (e.g., by way of a negative differential output signal) a coupled charge well, wherein the differential output signal is the result of white noise and is therefore symmetric on average. Thus, the coupled charge well remains unfilled over the interval of time in which the differential output signal is at the zero-null (e.g., white noise only) level. In cases wherein the differential output signal represents a non-noise output (e.g., a signal) and exceeds the zero-null noise floor, the coupled charge well can be filled (e.g., wherein negative outputs from the CCP that exceed a threshold value can be rectified as needed, wherein the charge well can be offset biased to allow positive or negative charge collection, etc.). Thus, the charge well (e.g., which can represent a CCD pixel) can optionally be read only upon reaching a threshold fill level (e.g., 80%, 100%, 50%, etc.), which prevents unnecessary reads and can save read system resources (e.g., computational resources, power resources, etc.). In some variations, charge well level can be used as a self-trigger for reading (e.g., as in Block S230) from the charge well.

Block S220 can include Block S224, which includes: combining a plurality of differential output signals generated at a plurality of CCPs into a single differential output signal. Block S224 functions to generate a collective output of a CCP array, wherein the CCPs of the CCP array are interconnected. Thus, Block S224 is preferably performed by a CCP array substantially as described above in Section 3, but can additionally or alternatively be performed by any suitable detector network. The CCP array can have any suitable connectivity, as described above in Section 3, wherein the connectivity between CCPs of the CCP array preferably dictates the manner in which differential output signals are combined (e.g., whether a single ternary output is generated for the entire array, whether a ternary output is generated for each of a plurality of clusters within the array, etc.).

Block S224 can be performed at various frequencies; for example, Block S224 can be performed a single time (e.g., encoding a key frame as a reference signal) at the start of a detection sequence (e.g., a staring mode detection sequence for a time interval, a sequence of framed image reads, etc.) and thereby detect differential outputs between the initial frame and any successive frames. In another example, Block S224 can be performed in response to detection of a collective output indicative of a change (e.g., other than logical zero) in one or more CCPs of the CCP array (e.g., and therefore in the input signal), such that differences between frames are tracked from frame to frame (e.g., based on repeated recompensation as in Block S204 to account for recent changes in the input signal). However, Block S224 can be otherwise suitably performed with any suitable temporal characteristics in relation to other Blocks of the method 200.

In relation to Block S224, the single differential output preferably encodes a ternary (e.g., trinary) logical output resulting from the combination of the plurality of differential output signals. A single ternary logical output can enable a single bit read of the CCP array (e.g., in Block S230), because logical output combination is performed in the analog optoelectronic domain among the plurality of CCPs of the array. The single bit read can include a cumulative AND operation, wherein a logical zero output of the CCP array is generated when each of the CCPs produces a logical zero output (e.g., the array is serially connected).

In a variation, Block S224 can include performing a comparison between a reference signal and the input signal at a CCP array. The comparison is preferably performed in the analog optoelectronic domain (e.g., within the network of the CCP array), but can additionally or alternatively be performed downstream of the CCP array (e.g., at a processor, microprocessor, in software, electrical circuitry, etc.). In an example, the reference signal can be encoded into the CCP array by compensating each of the CCPs in the array (e.g., as in Block S204) such that a balancing input signal (e.g., an input signal that balances the reference signal at each of the opposing detectors of the CCP array) generates a zero null (e.g., logical zero) output across the sense node and reference node of the linked CCP array. In another example, the reference signal can be encoded into the CCP array by way of the physical characteristics of the CCP array (e.g., the ratio between detector areas of each of the CCPs in the array which corresponds to a specific input signal asymmetry that generates a logical zero output at the CCP sense and reference nodes). In this variation, the comparison can be performed between the reference signal and the input signal at each CCP in the array (e.g., having a one-to-one correspondence between the number of detections and the number of comparisons output), at each of a set of clusters of CCPs in the array (e.g., having a one-to-many correspondence between the number of detections and the number of comparisons output), and/or at the collective serially connected CCP array (e.g., having a many-to-one correspondence between the number of detections and the number of comparisons output).

### 4.5 Analyzing

Block S230 includes: analyzing a differential output. Block S230 functions to utilize the analog computation performed in the CCP, CCP array, and/or other detector used in relation to portions of the method 200. Block S230 can also function to perform additional computation using the generated output(s) of the CCPs (e.g., as in Block S220 and variations thereof). The differential output can be the output of a single CCP, and/or the collective output of a plurality of CCPs arranged in a CCP array. Block S230 is preferably performed using a processor substantially as described above in Section 3, but can additionally or alternatively be performed using any suitable components capable of analog or digital signal analysis.

Block S230 preferably includes generating a result based on the analysis. The result can be a piece of information resulting from optical perception operations (e.g., information that an individual has entered a room monitored by a CCP sensor), a trigger (e.g., a zero crossing of the differential output signal has occurred, and an associated action ought to be performed), an optical center of mass (e.g., a relative location of an optical center of mass of a scene imaged onto a variation of the CCP array), a vector path of a moving object (e.g., observed during a sequence of frames collected from a CCP array), and any other suitable result.

In a variation, Block S230 can include detecting phase content in the differential signal. The detected phase content can be injected (e.g., as in Block S202) or present in the input signal naturally (e.g., without injection). In cases wherein the phase content is injected, Block S230 can include demodulating the differential output signal using the monitored phase content during injection, to remove common mode noise via lock-in phase-sensitive detection techniques. In some examples, phase content can include a resonance, and Block S230 can include detecting the resonance. In these examples and other related examples, Block S230 can include detecting the resonance based on a logical output of the CCP (e.g., wherein the output of the CCP is equal to logical zero when the input signal is resonant, and not equal to logical zero when the input signal is not resonant).

In a related variation, Block S230 can include reducing noise in a polarity encoded output signal (e.g., as in one or more variations of Block S220). In this variation, the frequency of polarity encoding (e.g., the rate or frequency at which polarity switches in the output signal) is preferably sufficiently high that the difference between an Nₜₕ sample (e.g., of a first polarity) and an Nₜₕ+1 sample (e.g., of an opposing polarity) is small, and the noise term that contributes to both the Nₜₕ and Nₜₕ+1 samples remains correlated over the time interval (e.g., the inverse of the frequency of polarity encoding) in which the points are sampled. Thus, the polarity-encoded samples can be re-combined (e.g., at an adding node that combines the opposite polarity signals) and the correlated portion of the noise will cancel, reducing the overall noise in the signal.

In another variation, Block S230 can include perceiving properties of an object based on the output. The object is preferably imaged by the CCP (e.g., an image of the object is projected onto the detection surface of the CCP), but can additionally or alternatively be indirectly perceived in the input signal due to interactions of the light source (e.g., from which the input signal originates) with the object (e.g., shadowing, scattering, refraction, reflection, etc.). In an example, this variation of Block S230 can include extracting particle characteristics based on the output; in particular, in a specific example, Block S230 can include extracting properties of multiple particles using a CCP detector pair, within the analog optoelectronic domain, and generating output signals at a sense node (e.g., without the need for complex electronics). The output signal waveforms generated at the sense node can classify particles and/or encode particle properties based on any one or combination of rise/fall times, positive/negative signal peaks, positive/negative slope inflections, long/short duty cycles and on/off cycles, symmetry attributes, and other suitable signal features.

In another variation, Block S230 can include triggering an action based on the output. The action can include: reading a signal value from a value-holding element (e.g., a charge well, a capacitor, a sample-hold circuit block, etc.), initiating an alarm (e.g., a visual alarm, an aural alarm, a haptic alarm, etc.), transmitting a message, re-compensating one or more CCP set points (e.g., zero null points), and any other suitable action. Triggering based on the output can include triggering in response to an output magnitude exceeding a threshold, based on an integrated output exceeding a threshold (e.g., integrated in a charge well), based on a determined optical center of mass falling within a predetermined region of the detector (e.g., within a predetermined segment of a synthetically rotatable CCP array), based on a ternary logic value output of a CCP and/or CCP array, and any other suitable basis. In a specific example, Block S230 can include triggering an action based on a zero-crossing of the differential output signal. In another specific example, Block S230 includes triggering a read of a charge well in response to the charge level in the charge well exceeding 50% of its capacity, wherein reading the charge well drains the charge well to zero, enabling resumption of operation in the staring mode (e.g., as in one or more variations of Block S222).

The systems and/or methods of the preferred embodiment and variations thereof can be embodied and/or implemented at least in part as a machine configured to receive a computer-readable medium storing computer-readable instructions. The instructions are preferably executed by computer-executable components preferably integrated with the system and one or more portions of the processor and/or the controller. The computer-readable medium can be stored on any suitable computer-readable media such as RAMs, ROMs, flash memory, EEPROMs, optical devices (CD or DVD), hard drives, floppy drives, or any suitable device. The computer-executable component is preferably a general or application specific processor, but any suitable dedicated hardware or hardware/firmware combination device can alternatively or additionally execute the instructions.

Although omitted for conciseness, the preferred embodiments include every combination and permutation of the various system components and/or method blocks.

The FIGURES illustrate the architecture, functionality and operation of possible implementations of systems, methods and computer program products according to preferred embodiments, example configurations, and variations thereof. In this regard, each block in the flowchart or block diagrams may represent a module, segment, step, or portion of code, which comprises one or more executable instructions for implementing the specified logical function(s). It should also be noted that, in some alternative implementations, the functions noted in the block can occur out of the order noted in the FIGURES. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. It will also be noted that functional behaviors of any one of the system components, subsystems, and/or variations thereof can be implemented as variations of blocks of the method, and that any one of the blocks of the method and variations thereof can be enabled and implemented as a combination of system components and/or variations thereof.

As a person skilled in the art will recognize from the previous detailed description and from the figures and claims, modifications and changes can be made to the preferred embodiments of the invention without departing from the scope of this invention defined in the following claims.

We claim:

1. A system for optical perception comprising:
a current confining pixel (CCP) comprising:
a first detector having a first polarity and defining a first detection surface, the first detection surface defining a first front side and a first back side,
a second detector having a second polarity opposing the first polarity and defining a second detection surface, the second detection surface defining a second front side and a second back side, electrically connected to the first detector in an inverted polarity configuration defining a loop, wherein the first and second detector are separated by a first width,
a sense node electrically connected along the loop between the first and second detector,
a reference node electrically connected along the loop between the first and second detector and at an opposing side of the loop from the sense node;
a first light source arranged to illuminate at least one of the first back side and the second back side with a reference signal, wherein the reference signal comprises an optical signal;
wherein, during operation, the CCP outputs a differential output signal across the sense node and the reference node, wherein the differential output signal value is based on a comparison between an input signal, received by at least one of the first front side and the second front side, and the reference signal.

2. The system of claim 1, wherein the first light source is arranged to symmetrically illuminate the first back side and the second back side with the reference signal.

3. The system of claim 2, wherein the magnitude of the reference signal is greater than the magnitude of the input signal.

4. The system of claim 1, further comprising a second light source arranged to illuminate at least one of the first front side and the second front side, wherein the second light source generates the input signal.

5. The system of claim 4, further comprising a source modulator that, during operation, injects phase content into the input signal generated by the second light source.

6. The system of claim 5, wherein the second light source is arranged to illuminate the first front side, wherein the second light source generates a first portion of the input signal, further comprising a third light source arranged to illuminate the second front side, wherein the third light source generates a second portion of the input signal, wherein the first front side opposes the second front side and the first and second front sides are distally spaced to form a sampling volume therebetween, and wherein the source modulator injects phase content into the first and second portions of the input signal by: operating the second light source in an on state and the third light source in an off state in a first mode; operating the second light source in the off state and the third light source in the on state in a second mode; and, alternating between the first mode and the second mode during operation.

7. The system of claim 4, further comprising a processor, wherein the first detector and second detector are subdivided into a set of electrode segments, wherein the processor, during operation, synthetically rotates the input signal, and wherein the differential output signal comprises an optical center of mass of the input signal.

8. The system of claim 1, further comprising a CCP modulator that, during operation, vibrates the CCP along a direction coplanar with the first and second detector surfaces and perpendicular to the first width.

9. The system of claim 8, wherein the differential output signal comprises a resonance signal, wherein the resonance signal frequency and magnitude are based on the first width.

10. The system of claim 1, wherein the first detection surface and the second detection surface are coplanar in a detection plane.

11. A method for optical perception comprising:
providing a current confining pixel (CCP) comprising:
a first detector having a first polarity,
a second detector having a second polarity opposing the first polarity, electrically connected to the first detector in an inverted polarity configuration defining a loop
a sense node electrically connected to the loop,
a reference node electrically connected to the loop at a side opposing the sense node;
receiving, at the CCP, an input signal, wherein the input signal comprises an optical signal;
compensating the CCP with a reference signal contemporaneously with receiving the input signal;
generating, across the sense node and the reference node and in an analog optoelectronic domain, a differential output signal based on the input signal;
generating an analysis of the differential output signal and providing the analysis at an output device.

12. The method of claim 11, further comprising modulating the input signal at a modulation frequency.

13. The method of claim 12, wherein the first and second detector are separated by a vernier line having a width, wherein generating the analysis comprises extracting a resonant frequency from the modulated input signal based on the width and the modulation frequency.

14. The method of claim 12, wherein modulating the input signal comprises modulating a position of the CCP relative to the input signal as a function of time.

15. The method of claim 14, wherein the CCP comprises a segmented electrode CCP, and wherein modulating the position of the CCP relative to the input signal comprises synthetically rotating the segmented electrode CCP.

16. The method of claim 11, wherein the reference signal comprises an optical signal.

17. The method of claim 16, wherein compensating the CCP comprises asymmetrically illuminating the CCP with the optical signal.

18. The method of claim 16, wherein compensating the CCP comprises symmetrically illuminating the CCP with the optical signal, wherein the magnitude of the optical signal is greater than the magnitude of the input signal.

19. The method of claim 11, wherein compensating the CCP comprises applying a symmetric bias voltage to the sense node and the reference node.

20. The method of claim 11, wherein the first detector and second detector each comprise a PIN photodiode.
